(19) United States
(12) Patent Application Publication
(10) Pub. No.: US 2023/0018394 A1
(43) Pub. Date: Jan. 19, 2023

(54) THREE-DIMENSIONAL MEMORY DEVICE INCLUDING AIRGAP CONTAINING INSULATING LAYERS AND METHOD OF MAKING THE SAME

(71) Applicant: SANDISK TECHNOLOGIES LLC, Addison, TX (US)

(72) Inventors: Raghuveer S. MAKALA, Campbell, CA (US); Senaka KANAKAMEDALA, San Jose, CA (US); Rahul SHARANGPANI, Fremont, CA (US); Ramy Nashed Bassely SAID, San Jose, CA (US)

(21) Appl. No.: 17/378,196

(22) Filed: Jul. 16, 2021

(51) Int. Cl. H01L 27/1157; H01L 27/11519; H01L 27/11556; H01L 27/11524; H01L 27/11565; H01L 27/11582; H01L 29/06

(52) U.S. Cl. CPC H01L 27/1157; H01L 27/11519; H01L 27/11556; H01L 27/11524; H01L 27/11565; H01L 27/11582; H01L 29/0649

(57) ABSTRACT

A three-dimensional memory device includes a vertical repetition of multiple instances of a unit layer stack. The unit layer stack includes, in order, an airgap-containing insulating layer, a first interfacial dielectric capping layer, a metal layer, and a second interfacial dielectric capping layer. Memory stack structures extend through the vertical repetition. Each of the memory stack structures includes a vertical semiconductor channel and a vertical stack of memory elements located at levels of the metal layers.

### FIELD

The present disclosure relates generally to the field of semiconductor devices, and particularly to a three-dimensional memory device including airgap-containing insulating layers and methods of manufacturing the same.

### BACKGROUND

Three-dimensional vertical NAND strings having one bit per cell are disclosed in an article by T. Endoh et al., titled “Novel Ultra High Density Memory With A Stacked-Surrounding Gate Transistor (S-SGT) Structured Cell”, IEDM Proc. (2001) 33-36.

### SUMMARY

According to an aspect of the present disclosure, a three-dimensional memory device is provided, which comprises: a vertical repetition of multiple instances of a unit layer stack located over a substrate, wherein the unit layer stack comprises, in order, an airgap-containing insulating layer, a first interfacial dielectric capping layer, a metal layer, and a second interfacial dielectric capping layer; and memory stack structures extending through the vertical repetition, wherein each of the memory stack structures comprises a vertical semiconductor channel and a vertical stack of memory elements located at levels of the metal layers.

According to another aspect of the present disclosure, a method of forming a three-dimensional memory device is provided, which comprises: forming a vertical repetition of multiple instances of a unit layer stack located over a substrate, wherein the unit layer stack comprises, in order, a sacrificial material layer, a first interfacial dielectric capping layer, a metal layer, and a second interfacial dielectric capping layer; forming memory openings through the vertical repetition; forming memory opening fill structures in the memory openings, wherein each of the memory opening fill structures comprises a vertical semiconductor channel and a vertical stack of memory elements located at levels of the metal layers; and replacing instances of the sacrificial material layer within the vertical repetition with instances of an insulating layer.

### BRIEF DESCRIPTION OF THE DRAWINGS

FIG. 1 is a schematic vertical cross-sectional view of an exemplary structure after formation of at least one peripheral device, a semiconductor material layer, and a gate dielectric layer according to an embodiment of the present disclosure.

FIG. 2 is a schematic vertical cross-sectional view of the exemplary structure after formation of a vertical repetition of multiple instances of a unit layer stack located over a substrate, wherein the unit layer stack comprises, in order, a sacrificial material layer, a first interfacial dielectric capping layer, a metal layer, and a second interfacial dielectric capping layer according to an embodiment of the present disclosure.

FIG. 3 is a schematic vertical cross-sectional view of the exemplary structure after formation of stepped terraces, a retro-stepped dielectric material portion, and drain-select-level isolation structures according to an embodiment of the present disclosure.

FIG. 4A is a schematic vertical cross-sectional view of the exemplary structure after formation of memory openings and support openings according to an embodiment of the present disclosure.

FIG. 4B is a top-down view of the exemplary structure of FIG. 4A. The vertical plane A-A′ is the plane of the cross-section for FIG. 4A.

FIGS. 5A-5H are sequential schematic vertical cross-sectional views of a memory opening within the exemplary structure during formation of a memory stack structure, an optional dielectric core, and a drain region therein according to an embodiment of the present disclosure.

FIG. 6 is a schematic vertical cross-sectional view of the exemplary structure after formation of memory stack structures and support pillar structures according to an embodiment of the present disclosure.

FIG. 7A is a schematic vertical cross-sectional view of the exemplary structure after formation of backside trenches according to an embodiment of the present disclosure.

FIG. 7B is a partial see-through top-down view of the exemplary structure of FIG. 7A. The vertical plane A-A′ is the plane of the schematic vertical cross-sectional view of FIG. 7A.

FIG. 8A is a schematic vertical cross-sectional view of the exemplary structure after formation of backside recesses according to an embodiment of the present disclosure.

FIG. 8B is a magnified view of a region in FIG. 8A.

FIG. 9A is a vertical cross-sectional view of the exemplary structure after formation of airgap-containing insulating layers according to an embodiment of the present disclosure.

FIG. 9B is a magnified view of a region in FIG. 9A.

FIG. 10 is a schematic vertical cross-sectional view of the exemplary structure after formation of an insulating spacer and a backside contact structure in each backside trench according to an embodiment of the present disclosure.

FIG. 11A is a schematic vertical cross-sectional view of the exemplary structure after formation of additional contact via structures according to an embodiment of the present disclosure.

FIG. 11B is a top-down view of the exemplary structure of FIG. 11A. The vertical plane A-A′ is the plane of the schematic vertical cross-sectional view of FIG. 11A.

FIG. 12 is a vertical cross-sectional view of an alternative configuration of the exemplary structure after isotropically etching physically exposed portions of at least one blocking dielectric layer and a memory material layer within each memory film according to an embodiment of the present disclosure.

FIG. 13 is a vertical cross-sectional view of the alternative configuration of the exemplary structure after formation of airgap-containing insulating layers in the backside recesses according to an embodiment of the present disclosure.

FIG. 14 is a vertical cross-sectional view of the alternative configuration of the exemplary structure after formation of backside trench fill structures and contact via structures according to an embodiment of the present disclosure.

### DETAILED DESCRIPTION

As discussed above, the present disclosure is directed to a three-dimensional memory device including airgap-containing insulating layers and methods of manufacturing the same, the various aspects of which are described below. The embodiments of the disclosure can be employed to form various structures including a multilevel memory structure, non-limiting examples of which include semiconductor devices such as three-dimensional memory array devices comprising a plurality of NAND memory strings.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The term “at least one” element refers to all possibilities including the possibility of a single element and the possibility of multiple elements.

The same reference numerals refer to the same element or similar element. Unless otherwise indicated, elements having the same reference numerals are presumed to have the same composition and the same function. Unless otherwise indicated, a “contact” between elements refers to a direct contact between elements that provides an edge or a surface shared by the elements. If two or more elements are not in direct contact with each other or among one another, the two elements are “disjoined from” each other or “disjoined among” one another. As used herein, a first element located “on” a second element can be located on the exterior side of a surface of the second element or on the interior side of the second element. As used herein, a first element is located “directly on” a second element if there exist a physical contact between a surface of the first element and a surface of the second element. As used herein, a first element is “electrically connected to” a second element if there exists a conductive path consisting of at least one conductive material between the first element and the second element. As used herein, a “prototype” structure or an “in-process” structure refers to a transient structure that is subsequently modified in the shape or composition of at least one component therein.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the continuous structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, or may have one or more layer thereupon, thereabove, and/or therebelow.

Generally, a semiconductor die, or a semiconductor package, can include a memory chip. Each semiconductor package contains one or more dies (for example one, two, or four). The die is the smallest unit that can independently execute commands or report status. Each die contains one or more planes (typically one or two). Identical, concurrent operations can take place on each plane, although with some restrictions. Each plane contains a number of blocks, which are the smallest unit that can be erased by in a single erase operation. Each block contains a number of pages, which are the smallest unit that can be programmed, i.e., a smallest unit on which a read operation can be performed.

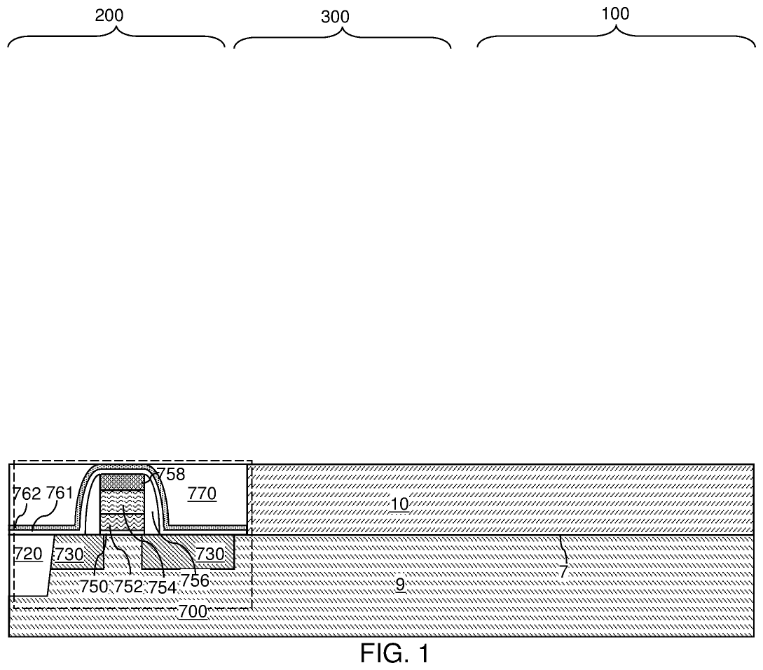

Referring to FIG. 1, an exemplary structure according to an embodiment of the present disclosure is illustrated, which can be employed, for example, to fabricate a device structure containing vertical NAND memory devices. The exemplary structure includes a substrate (9, 10), which can be a semiconductor substrate. The substrate can include a substrate semiconductor layer 9 and an optional semiconductor material layer 10. The substrate semiconductor layer 9 maybe a semiconductor wafer or a semiconductor material layer, and can include at least one elemental semiconductor material (e.g., single crystal silicon wafer or layer), at least one III-V compound semiconductor material, at least one II-VI compound semiconductor material, at least one organic semiconductor material, or other semiconductor materials known in the art. The substrate can have a major surface 7, which can be, for example, a topmost surface of the substrate semiconductor layer 9. The major surface 7 can be a semiconductor surface. In one embodiment, the major surface 7 can be a single crystalline semiconductor surface, such as a single crystalline semiconductor surface.

As used herein, a “semiconducting material” refers to a material having electrical conductivity in the range from 1.0×10⁻⁶ S/cm to 1.0×10⁵ S/cm. As used herein, a “semiconductor material” refers to a material having electrical conductivity in the range from 1.0×10⁻⁶ S/cm to 1.0×10⁵ S/cm in the absence of electrical dopants therein, and is capable of producing a doped material having electrical conductivity in a range from 1.0 S/cm to 1.0×10⁵ S/cm upon suitable doping with an electrical dopant. As used herein, an “electrical dopant” refers to a p-type dopant that adds a hole to a valence band within a band structure, or an n-type dopant that adds an electron to a conduction band within a band structure. As used herein, a “conductive material” refers to a material having electrical conductivity greater than 1.0×10⁵ S/cm. As used herein, an “insulator material” or a “dielectric material” refers to a material having electrical conductivity less than 1.0×10⁻⁶ S/cm. As used herein, a “heavily doped semiconductor material” refers to a semiconductor material that is doped with electrical dopant at a sufficiently high atomic concentration to become a conductive material either as formed as a crystalline material or if converted into a crystalline material through an anneal process (for example, from an initial amorphous state), i.e., to have electrical conductivity greater than 1.0×10⁵ S/cm. A “doped semiconductor material” may be a heavily doped semiconductor material, or may be a semiconductor material that includes electrical dopants (i.e., p-type dopants and/or n-type dopants) at a concentration that provides electrical conductivity in the range from 1.0×10⁻⁶ S/cm to 1.0×10⁵ S/cm. An “intrinsic semiconductor material” refers to a semiconductor material that is not doped with electrical dopants. Thus, a semiconductor material may be semiconducting or conductive, and may be an intrinsic semiconductor material or a doped semiconductor material. A doped semiconductor material can be semiconducting or conductive depending on the atomic concentration of electrical dopants therein. As used herein, a “metallic material” refers to a conductive material including at least one metallic element therein. All measurements for electrical conductivities are made at the standard condition.

At least one semiconductor device 700 for a peripheral circuitry can be formed on a portion of the substrate semiconductor layer 9. The at least one semiconductor device can include, for example, field effect transistors. For example, at least one shallow trench isolation structure 720 can be formed by etching portions of the substrate semiconductor layer 9 and depositing a dielectric material therein. A gate dielectric layer, at least one gate conductor layer, and a gate cap dielectric layer can be formed over the substrate semiconductor layer 9, and can be subsequently patterned to form at least one gate structure (750, 752, 754, 758), each of which can include a gate dielectric 750, a gate electrode (752, 754), and a gate cap dielectric 758. The gate electrode (752, 754) may include a stack of a first gate electrode portion 752 and a second gate electrode portion 754. At least one gate spacer 756 can be formed around the at least one gate structure (750, 752, 754, 758) by depositing and anisotropically etching a dielectric liner. Active regions 730 can be formed in upper portions of the substrate semiconductor layer 9, for example, by introducing electrical dopants employing the at least one gate structure (750, 752, 754, 758) as masking structures. Additional masks may be employed as needed. The active region 730 can include source regions and drain regions of field effect transistors. A first dielectric liner 761 and a second dielectric liner 762 can be optionally formed. Each of the first and second dielectric liners (761, 762) can comprise a silicon oxide layer, a silicon nitride layer, and/or a dielectric metal oxide layer. As used herein, silicon oxide includes silicon dioxide as well as non-stoichiometric silicon oxides having more or less than two oxygen atoms for each silicon atoms. Silicon dioxide is preferred. In an illustrative example, the first dielectric liner 761 can be a silicon oxide layer, and the second dielectric liner 762 can be a silicon nitride layer. The least one semiconductor device for the peripheral circuitry can contain a driver circuit for memory devices to be subsequently formed, which can include at least one NAND device.

A dielectric material such as silicon oxide can be deposited over the at least one semiconductor device, and can be subsequently planarized to form a planarization dielectric layer 770. In one embodiment the planarized top surface of the planarization dielectric layer 770 can be coplanar with a top surface of the dielectric liners (761, 762). Subsequently, the planarization dielectric layer 770 and the dielectric liners (761, 762) can be removed from an area to physically expose a top surface of the substrate semiconductor layer 9. As used herein, a surface is “physically exposed” if the surface is in physical contact with vacuum, or a gas phase material (such as air).

The optional semiconductor material layer 10, if present, can be formed on the top surface of the substrate semiconductor layer 9 prior to, or after, formation of the at least one semiconductor device 700 by deposition of a single crystalline semiconductor material, for example, by selective epitaxy. The deposited semiconductor material can be the same as, or can be different from, the semiconductor material of the substrate semiconductor layer 9. The deposited semiconductor material can be any material that can be employed for the substrate semiconductor layer 9 as described above. The single crystalline semiconductor material of the semiconductor material layer 10 can be in epitaxial alignment with the single crystalline structure of the substrate semiconductor layer 9. Portions of the deposited semiconductor material located above the top surface of the planarization dielectric layer 170 can be removed, for example, by chemical mechanical planarization (CMP). In this case, the semiconductor material layer 10 can have a top surface that is coplanar with the top surface of the planarization dielectric layer 770.

The region (i.e., area) of the at least one semiconductor device 700 is herein referred to as a peripheral device region 200. The region in which a memory array is subsequently formed is herein referred to as a memory array region 100. A contact region 300 for subsequently forming stepped terraces of metal layers can be provided between the memory array region 100 and the peripheral device region 200.

In one alternative embodiment, the peripheral device region 200 containing the at least one semiconductor device 700 for a peripheral circuitry may be located under the memory array region 100 in a CMOS under array configuration. In another alternative embodiment, the peripheral device region 200 may be located on a separate substrate which is subsequently bonded to the memory array region 100.

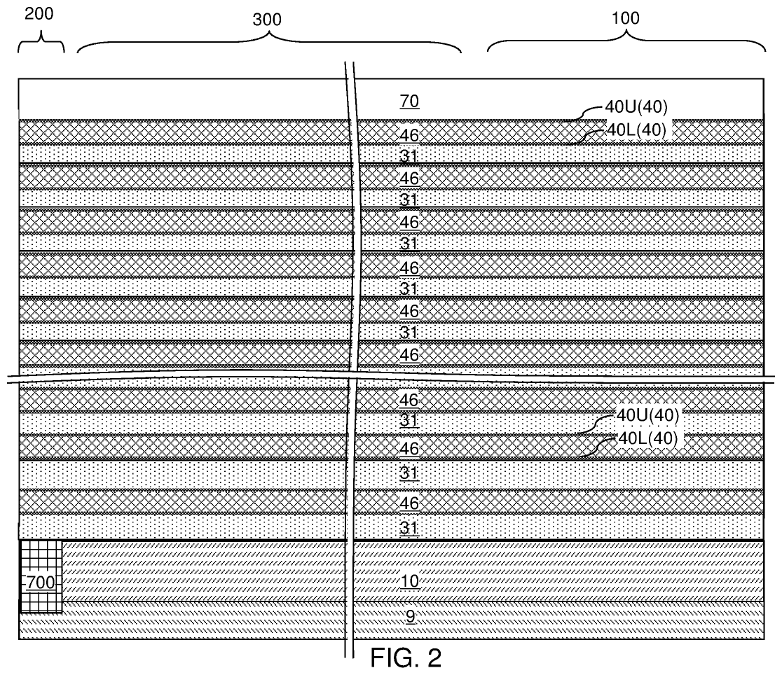

Referring to FIG. 2, a vertical repetition of multiple instances of a unit layer stack (31, 40L, 46, 40U) can be formed located over the substrate (9, 10). The unit layer stack (31, 40L, 46, 40U) can comprise, in order either from bottom to top or from top to bottom, a sacrificial material layer 31, a first interfacial dielectric capping layer 40L, a metal layer 46, and a second interfacial dielectric capping layer 40U. The first interfacial dielectric capping layers 40L and the second interfacial dielectric capping layers 40U are herein collectively referred to as interfacial dielectric capping layers 40.

Each sacrificial material layer 31 includes a material that can be subsequently removed selective to the material of the semiconductor material layer 10, the interfacial dielectric capping layers 40, and the dielectric material of a retro-stepped dielectric material portion to be subsequently formed. For example, the sacrificial material layers 31 may include, and/or may consist essentially of, silicon oxide, silicon nitride, organosilicate glass, or borosilicate glass. Organosilicate glass and borosilicate glass may be etched in dilute hydrofluoric acid at an etch rate that is at least 100 times, such as at least 1,000 times, the etch rate of undoped silicate glass in dilute hydrofluoric acid. Silicon nitride may be etched in hot phosphoric acid at an etch rate that is at least 10 times, such as at least 100 times, the etch rate of undoped silicate glass in hot phosphoric acid. The sacrificial material layers 31 may be deposited, for example, by chemical vapor deposition or ion beam deposition. For example, silicon nitride layers may be deposited by reactive ion beam deposition in which a nitrogen ion and/or noble gas ion (e.g., Ar or Kr) beam is directed onto a silicon sputtering target to deposit a silicon nitride layer over the substrate (9, 10) which is positioned in the deposition chamber facing the target. Each of the sacrificial material layers 31 may have a thickness in a range from 10 nm to 60 nm, such as from 15 nm to 30 nm, although lesser and greater thicknesses may also be employed.

Each metal layer 46 includes an elemental metal or a metal alloy material. For example, the metal layers 46 may include, and/or may consist essentially of, a refractory metal such as molybdenum, niobium, tantalum, or tungsten, a transition metal having a high melting point such as ruthenium or cobalt, or a conductive metallic nitride material such as TiN, TaN, MoN or WN. In one embodiment, each metal layer 46 may comprise, and/or may consist essentially of, molybdenum. The metal layers 46 can be deposited by physical vapor deposition (e.g., ion beam deposition or sputtering), chemical vapor deposition or atomic layer deposition employing a molybdenum-containing precursor gas. For example, if the metal layers 46 comprise and/or consist essentially of molybdenum, then a non-reactive ion beam deposition process may be used to sputter molybdenum from a molybdenum sputtering target using a noble gas (e.g., argon or krypton) ion beam to deposit molybdenum layers 46 on the sacrificial material layers 31. In one embodiment, each instance of the metal layer 46 may comprise molybdenum at an atomic percentage that is greater than 90%, such as from 95% to 100%. Each of the sacrificial material layers 31 may have a thickness in a range from 10 nm to 60 nm, such as from 15 nm to 30 nm, although lesser and greater thicknesses may also be employed.

The first interfacial dielectric capping layers 40L and the second interfacial dielectric capping layers 40U include a respective oxygen-free dielectric material that is different from the material of the sacrificial material layers 31. In one embodiment, the first interfacial dielectric capping layers 40L comprise, and/or consists essentially of, a first oxygen-free dielectric material, and the second interfacial dielectric capping layers 40U comprise, and/or consist essentially of, a second oxygen-free dielectric material. In one embodiment, the first oxygen-free dielectric material and the second oxygen-free dielectric material may be oxygen-blocking dielectric barrier materials. In one embodiment, the first oxygen-free dielectric material may be selected from silicon carbide, silicon nitride, or silicon carbide nitride (i.e., silicon carbonitride), and the second oxygen-free dielectric material is selected from silicon carbide, silicon nitride, or silicon carbide nitride.

In one embodiment, the average thickness of instances of the first interfacial dielectric capping layer 40L can be less than 20%, and/or can be in a range from 2% to 10%, of the average thickness of instances of the metal layer 46, and the average thickness of instances of the second interfacial dielectric capping layer 40U can be less than 20%, and/or can be in a range from 2% to 10%, of the average thickness of the instances of the metal layer 46. In one embodiment, each of the first interfacial dielectric capping layers 40L and the second interfacial dielectric capping layers 40U may have a thickness in a range from 0.5 nm to 3 nm, such as from 1 nm to 2 nm, although lesser and greater thicknesses may also be employed.

The number of repetitions of the pairs of unit layer stack (31, 40L, 46, 40U) can be in a range from 2 to 1,024, and typically from 8 to 256, although a greater number of repetitions can also be employed. The middle metal layers 46 function as gate electrodes (e.g., control gate electrodes/word lines. One or more top and bottom gate electrodes in the vertical repetition of the unit layer stack (31, 40L, 46, 40U) may function as the select gate electrodes. In one embodiment, each sacrificial material layer 31 in the vertical repetition of the unit layer stack (31, 40L, 46, 40U) can have a uniform thickness that is substantially invariant within each respective sacrificial material layer 31.

Optionally, an insulating cap layer 70 can be formed over the vertical repetition of the unit layer stack (31, 40L, 46, 40U). The insulating cap layer 70 includes a dielectric material that is different from the material of the sacrificial material layers 31. For example, the insulating cap layer 70 may comprise undoped silicate glass (i.e., silicon oxide). The insulating cap layer 70 can be deposited, for example, by chemical vapor deposition or ion beam deposition. The insulating cap layer 70 can have a greater thickness than each of the sacrificial material layers 31. For example, the insulating cap layer 70 may have a thickness in a range from 10 nm to 100 nm, such as from 30 nm to 50 nm, although lesser and greater thicknesses may also be employed.

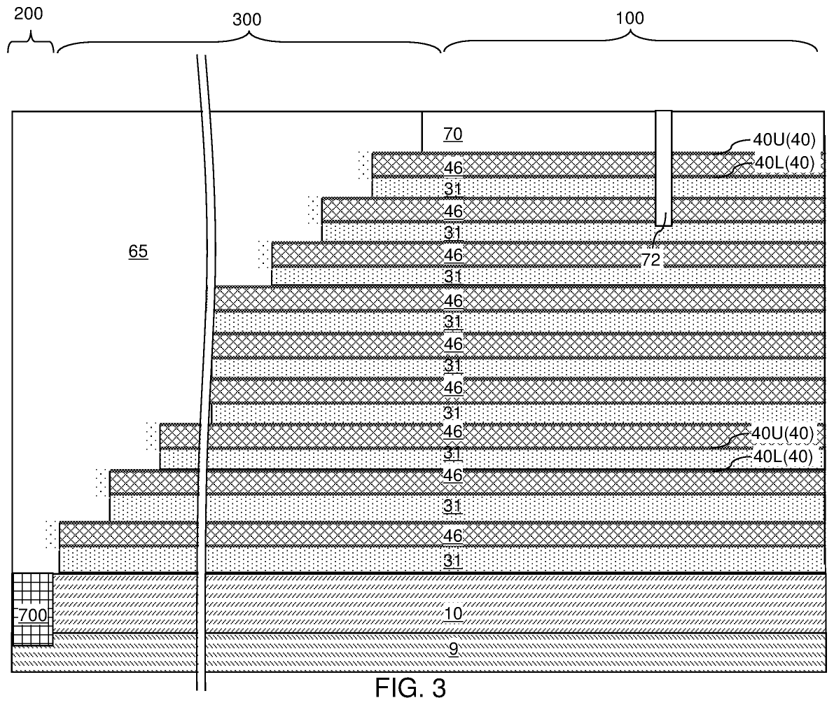

Referring to FIG. 3, stepped surfaces are formed at a peripheral region of the vertical repetition of the unit layer stack (31, 40L, 46, 40U), which is herein referred to as a terrace region. As used herein, “stepped surfaces” refer to a set of surfaces that include at least two horizontal surfaces and at least two vertical surfaces such that each horizontal surface is adjoined to a first vertical surface that extends upward from a first edge of the horizontal surface, and is adjoined to a second vertical surface that extends downward from a second edge of the horizontal surface. A stepped cavity is formed within the volume from which portions of the vertical repetition of the unit layer stack (31, 40L, 46, 40U) are removed through formation of the stepped surfaces. A “stepped cavity” refers to a cavity having stepped surfaces.

The terrace region is formed in the contact region 300, which is located between the memory array region 100 and the peripheral device region 200 containing the at least one semiconductor device for the peripheral circuitry. The stepped cavity can have various stepped surfaces such that the horizontal cross-sectional shape of the stepped cavity changes in steps as a function of the vertical distance from the top surface of the substrate (9, 10). In one embodiment, the stepped cavity can be formed by repetitively performing a set of processing steps. The set of processing steps can include, for example, an etch process of a first type that vertically increases the depth of a cavity by one or more levels, and an etch process of a second type that laterally expands the area to be vertically etched in a subsequent etch process of the first type. As used herein, a “level” of a structure including alternating plurality is defined as the relative position of a pair of a first material layer and a second material layer within the structure.

Each metal layer 46 other than a topmost metal layer 46 within the vertical repetition of the unit layer stack (31, 40L, 46, 40U) laterally extends farther than any overlying metal layer 46 within the vertical repetition of the unit layer stack (31, 40L, 46, 40U) in the terrace region. The terrace region includes stepped surfaces of the vertical repetition of the unit layer stack (31, 40L, 46, 40U) that continuously extend from a bottommost layer within the vertical repetition of the unit layer stack (31, 40L, 46, 40U) to a topmost layer within the vertical repetition of the unit layer stack (31, 40L, 46, 40U).

Each vertical step of the stepped surfaces can have the height of one or more instances of the unit layer stack (31, 40L, 46, 40U). In one embodiment, each vertical step can have the height of a single pair of a single instance of the unit layer stack (31, 40L, 46, 40U). In another embodiment, multiple “columns” of staircases can be formed along a first horizontal direction hd1 such that each vertical step has the height of a plurality of instances of the unit layer stack (31, 40L, 46, 40U), and the number of columns can be at least the number of the plurality of instances of the unit layer stack (31, 40L, 46, 40U).

A retro-stepped dielectric material portion 65 (i.e., an insulating fill material portion) can be formed in the stepped cavity by deposition of a dielectric material therein. For example, a dielectric material such as silicon oxide can be deposited in the stepped cavity. Excess portions of the deposited dielectric material can be removed from above the top surface of the insulating cap layer 70, for example, by chemical mechanical planarization (CMP). The remaining portion of the deposited dielectric material filling the stepped cavity constitutes the retro-stepped dielectric material portion 65. As used herein, a “retro-stepped” element refers to an element that has stepped surfaces and a horizontal cross-sectional area that increases monotonically as a function of a vertical distance from a top surface of a substrate on which the element is present. In one embodiment, the retro-stepped dielectric material portion 65 may comprise undoped silicate glass.

Optionally, drain-select-level isolation structures 72 can be formed through the insulating cap layer 70 and a subset of the metal layers 46 located at drain select levels. The drain-select-level isolation structures 72 can be formed, for example, by forming drain-select-level isolation trenches and filling the drain-select-level isolation trenches with a dielectric material such as silicon oxide. Excess portions of the dielectric material can be removed from above the top surface of the insulating cap layer 70.

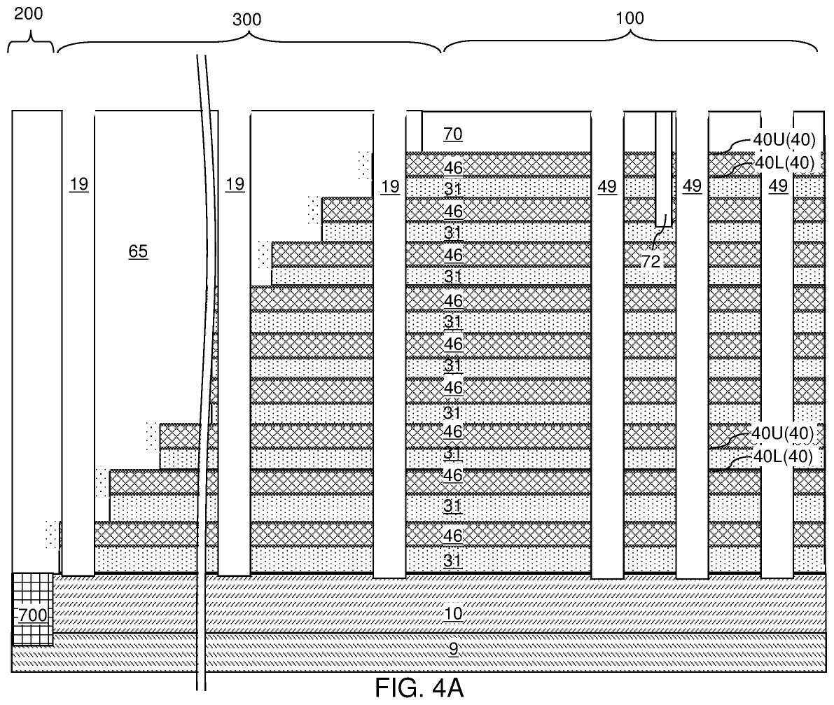

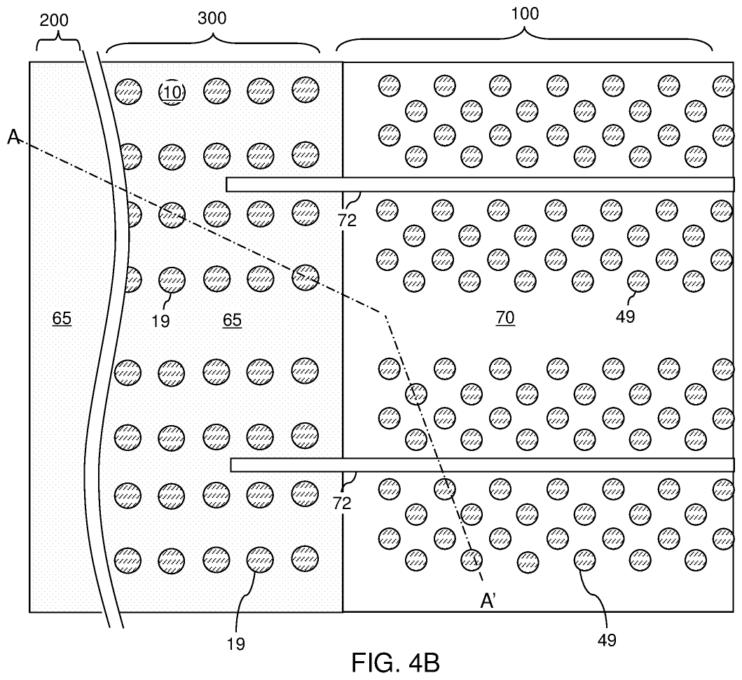

Referring to FIGS. 4A and 4B, a lithographic material stack (not shown) including at least a photoresist layer can be formed over the insulating cap layer 70 and the retro-stepped dielectric material portion 65, and can be lithographically patterned to form openings therein. The openings include a first set of openings formed over the memory array region 100 and a second set of openings formed over the contact region 300. The pattern in the lithographic material stack can be transferred through the insulating cap layer 70 or the retro-stepped dielectric material portion 65, and through the vertical repetition of the unit layer stack (31, 40L, 46, 40U) by at least one anisotropic etch that employs the patterned lithographic material stack as an etch mask. Portions of the vertical repetition of the unit layer stack (31, 40L, 46, 40U) underlying the openings in the patterned lithographic material stack are etched to form memory openings 49 and support openings 19. As used herein, a “memory opening” refers to a structure in which memory elements, such as a memory stack structure, is subsequently formed. As used herein, a “support opening” refers to a structure in which a support structure (such as a support pillar structure) that mechanically supports other elements is subsequently formed. The memory openings 49 are formed through the insulating cap layer 70 and the entirety of the vertical repetition of the unit layer stack (31, 40L, 46, 40U) in the memory array region 100. The support openings 19 are formed through the retro-stepped dielectric material portion 65 and the portion of the vertical repetition of the unit layer stack (31, 40L, 46, 40U) that underlie the stepped surfaces in the contact region 300.

The memory openings 49 extend through the entirety of the vertical repetition of the unit layer stack (31, 40L, 46, 40U). The support openings 19 extend through a subset of layers within the vertical repetition of the unit layer stack (31, 40L, 46, 40U). The chemistry of the anisotropic etch process employed to etch through the materials of the vertical repetition of the unit layer stack (31, 40L, 46, 40U) can alternate to optimize etching of the first and second materials in the vertical repetition of the unit layer stack (31, 40L, 46, 40U). The anisotropic etch can be, for example, a series of reactive ion etches. The sidewalls of the memory openings 49 and the support openings 19 can be substantially vertical, or can be tapered.

In an illustrative example, if the sacrificial material layers 31 include silicon oxide and if the metal layers 46 include molybdenum, the anisotropic etch process may employ an etch chemistry including an etchant including SF₆, CF₄, NF₃, Cl₂, CCl₄, CCl₂F₂, CF₃Cl₂, and/or HBr and optionally an oxidant (e.g., O₂). For example, molybdenum may be reactively ion etched using CCl₄/O₂ or CF₄/O₂, or plasma etched in NF₃, or ion beam etched with argon or other noble gas. In another illustrative example, if the sacrificial material layers 31 include silicon nitride and if the metal layers 46 include molybdenum, the anisotropic etch process may employ an etch chemistry including an etchant including CₓF_{y}Hz, CF₄, NF₃, Cl₂, CCl₄, CCl₂F₂, CF₃Cl₂, and/or HBr and optionally an oxidant of O₂. In this case, the etch byproduct may include MoOₓ, MoFₓ, MoClₓ, MoOClₓ, CNF, FCN, CFₓ, SiF_{y}, SiCl_{y}, COₓ, and/or COFₓ. In such etch chemistries, high vapor pressure etch products, such as MoF₆ may be formed. Use of Cl₂ may prevent or reduce undercutting. Avoiding formation of low-vapor-pressure molybdenum products, such as MoCl₆ can prevent reduction of the etch rate. Increasing the partial pressure of O₂ can increase the volatility of etch byproducts, and can prevent or reduce carbonation of molybdenum surfaces. If the metal layers 46 include a different metal, the etch chemistry may be accordingly adjusted to optimize the etch profile and the etch rate of the vertical repetition of the unit layer stack (31, 40L, 46, 40U). The patterned lithographic material stack can be subsequently removed, for example, by ashing.

The memory openings 49 and the support openings 19 can extend from the top surface of the vertical repetition of the unit layer stack (31, 40L, 46, 40U) to at least the horizontal plane including the topmost surface of the semiconductor material layer 10. In one embodiment, an overetch into the semiconductor material layer 10 may be optionally performed after the top surface of the semiconductor material layer 10 is physically exposed at a bottom of each memory opening 49 and each support opening 19. The overetch may be performed prior to, or after, removal of the lithographic material stack. In other words, the recessed surfaces of the semiconductor material layer 10 may be vertically offset from the un-recessed top surfaces of the semiconductor material layer 10 by a recess depth. The recess depth can be, for example, in a range from 1 nm to 50 nm, although lesser and greater recess depths can also be employed. The overetch is optional, and may be omitted. If the overetch is not performed, the bottom surfaces of the memory openings 49 and the support openings 19 can be coplanar with the topmost surface of the semiconductor material layer 10.

Each of the memory openings 49 and the support openings 19 may include a sidewall (or a plurality of sidewalls) that extends substantially perpendicular to the topmost surface of the substrate. A two-dimensional array of memory openings 49 can be formed in the memory array region 100. A two-dimensional array of support openings 19 can be formed in the contact region 300. The substrate semiconductor layer 9 and the semiconductor material layer 10 collectively constitutes a substrate (9, 10), which can be a semiconductor substrate. Alternatively, the semiconductor material layer 10 may be omitted, and the memory openings 49 and the support openings 19 can be extend to a top surface of the substrate semiconductor layer 9.

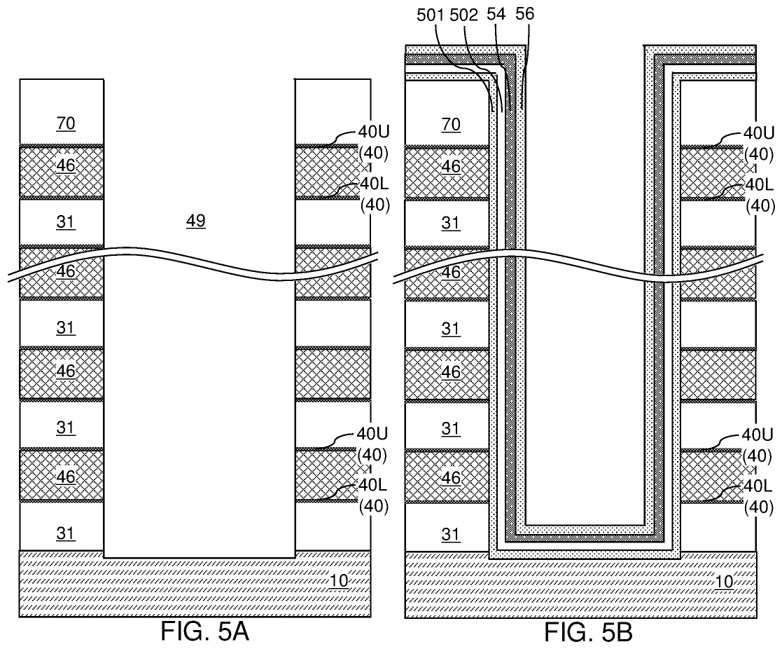

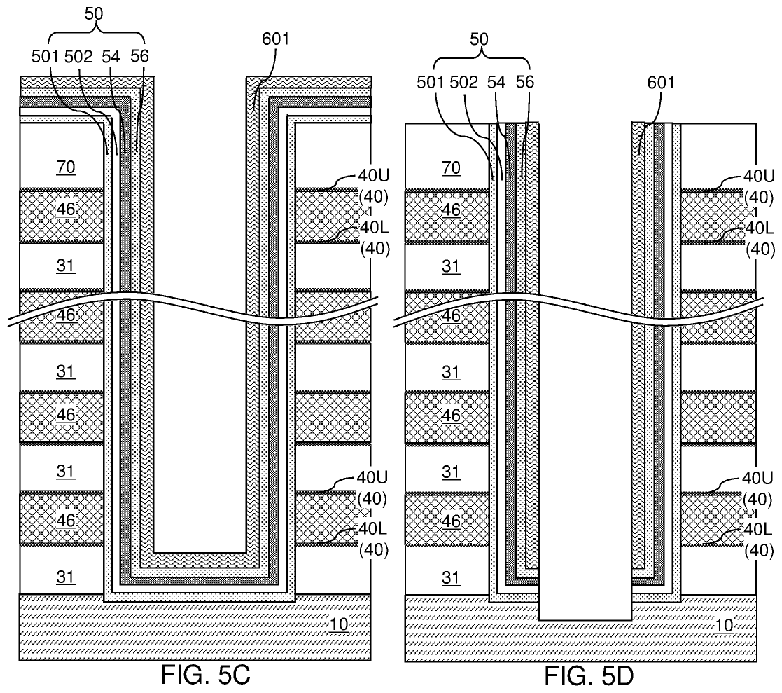

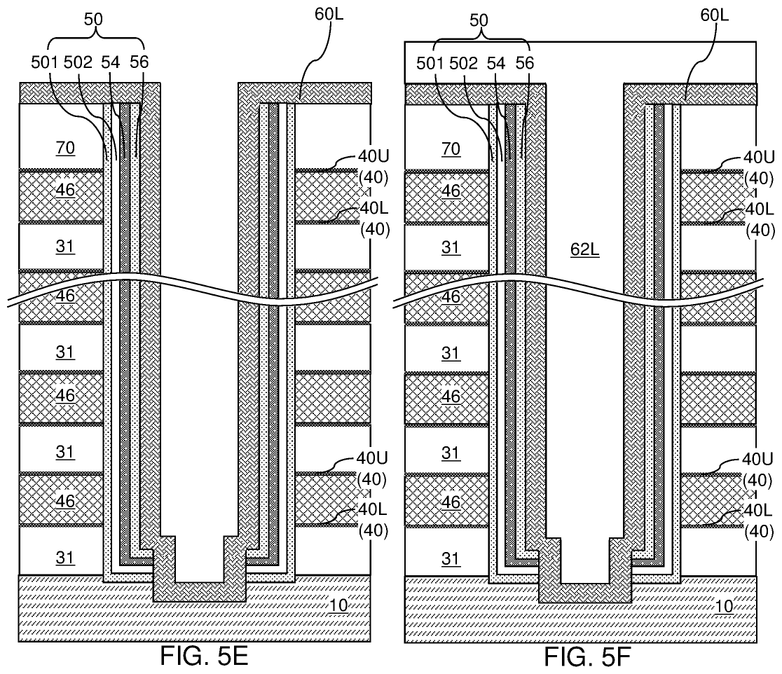

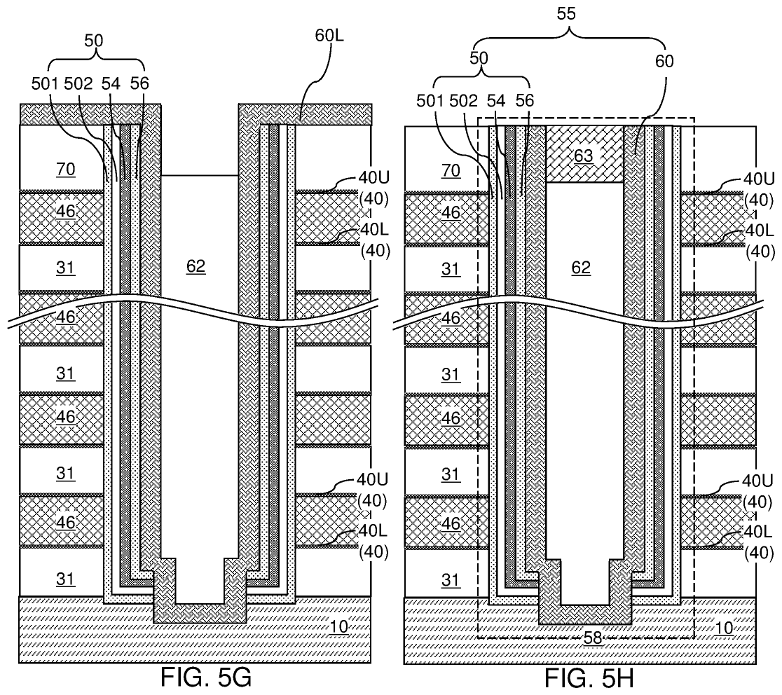

FIGS. 5A-5H illustrate structural changes in a memory opening 49, which is one of the memory openings 49 in the exemplary structure of FIGS. 4A and 4B. The same structural change occurs simultaneously in each of the other memory openings 49 and in each support opening 19.

Referring to FIG. 5A, a memory opening 49 in the exemplary device structure of FIGS. 4A and 4B is illustrated. The memory opening 49 extends through the insulating cap layer 70, the vertical repetition of the unit layer stack (31, 40L, 46, 40U), and optionally into an upper portion of the semiconductor material layer 10. At this processing step, each support opening 19 can extend through the retro-stepped dielectric material portion 65, a subset of layers in the vertical repetition of the unit layer stack (31, 40L, 46, 40U), and optionally through the upper portion of the semiconductor material layer 10. The recess depth of the bottom surface of each memory opening with respect to the top surface of the semiconductor material layer 10 can be in a range from 0 nm to 30 nm, although greater recess depths can also be employed. Optionally, the metal layers 46 can be laterally recessed partially to form lateral recesses (not shown), for example, by an isotropic etch.

Referring to FIG. 5B, a stack of layers including at least one blocking dielectric layer (501, 502), a memory material layer 54, and a dielectric material liner 56 can be sequentially deposited in the memory openings 49 by a respective conformal deposition process.

The at least one blocking dielectric layer (501, 502) can include a single dielectric material layer or a stack of a plurality of dielectric material layers. The at least one blocking dielectric layer (501, 502) can be formed employing a conformal deposition process. In one embodiment, the blocking dielectric layer (501, 502) can include layer stack of a first blocking dielectric layer 501 and a second blocking dielectric layer 502 that is formed on the first blocking dielectric layer 501.

In one embodiment, the first blocking dielectric layer 501 may comprise a dielectric metal oxide layer consisting essentially of a dielectric metal oxide. As used herein, a dielectric metal oxide refers to a dielectric material that includes at least one metallic element and at least oxygen. The dielectric metal oxide may consist essentially of the at least one metallic element and oxygen, or may consist essentially of the at least one metallic element, oxygen, and at least one non-metallic element such as nitrogen. In one embodiment, the first blocking dielectric layer 501 can include a dielectric metal oxide having a dielectric constant greater than 7.9, i.e., having a dielectric constant greater than the dielectric constant of silicon nitride.

Non-limiting examples of dielectric metal oxides include aluminum oxide (Al₂O₃), hafnium oxide (HfO₂), zirconium oxide (ZrO₂), lanthanum oxide (LaO₂), yttrium oxide (Y₂O₃), tantalum oxide (Ta₂O₅), silicates thereof, nitrogen-doped compounds thereof, alloys thereof, and stacks thereof. The dielectric metal oxide layer can be deposited, for example, by chemical vapor deposition (CVD), atomic layer deposition (ALD), pulsed laser deposition (PLD), liquid source misted chemical deposition, or a combination thereof. The thickness of the first blocking dielectric layer 501 can be in a range from 1 nm to 10 nm, although lesser and greater thicknesses can also be employed. The first blocking dielectric layer 501 can function as a dielectric material portion that blocks leakage of stored electrical charges to control gate electrodes. In one embodiment, the first blocking dielectric layer 501 includes aluminum oxide. In one embodiment, the first blocking dielectric layer 501 can include multiple dielectric metal oxide layers having different material compositions.

The second blocking dielectric layer 502 can include a dielectric semiconductor compound such as silicon oxide, silicon oxynitride or a combination thereof. In one embodiment, the second blocking dielectric layer 502 can include silicon oxide. In this case, the second blocking dielectric layer 502 can be formed by a conformal deposition method such as low pressure chemical vapor deposition, atomic layer deposition, or a combination thereof. The thickness of the second blocking dielectric layer 502 can be in a range from 1 nm to 10 nm, although lesser and greater thicknesses can also be employed.

Subsequently, the memory material layer 54 can be deposited as a continuous material layer by a conformal deposition process such as a chemical vapor deposition process or an atomic layer deposition process. The memory material layer 54 includes a memory material, i.e., a material that can store data by selecting a state of the material. For example, the memory material layer 54 may include a charge storage material such as silicon nitride, polysilicon, or a metallic material, a ferroelectric material that can store information in the form of a ferroelectric polarization direction, or any other memory material that can store date by altering its electrical resistivity.

The memory material layer 54 can be formed as a single memory material layer of homogeneous composition, or can include a stack of multiple memory material layers. In one embodiment, the memory material layer 54 may comprise an insulating charge trapping material, such as one or more silicon nitride segments. The memory material layer 54 can be formed, for example, by chemical vapor deposition (CVD), atomic layer deposition (ALD), physical vapor deposition (PVD), or any suitable deposition technique for storing electrical charges therein. The thickness of the memory material layer 54 can be in a range from 2 nm to 20 nm, although lesser and greater thicknesses can also be employed.

The dielectric material liner 56 includes a dielectric material. The dielectric material liner 56 can be formed on the memory material layer 54 employing a conformal deposition process. In one embodiment, the dielectric material liner 56 comprises a tunneling dielectric layer through which charge tunneling can be performed under suitable electrical bias conditions. The charge tunneling may be performed through hot-carrier injection or by Fowler-Nordheim tunneling induced charge transfer depending on the mode of operation of the monolithic three-dimensional NAND string memory device to be formed. The dielectric material liner 56 can include silicon oxide, silicon nitride, silicon oxynitride, dielectric metal oxides (such as aluminum oxide and hafnium oxide), dielectric metal oxynitride, dielectric metal silicates, alloys thereof, and/or combinations thereof. In one embodiment, the dielectric material liner 56 can include a stack of a first silicon oxide layer, a silicon oxynitride layer, and a second silicon oxide layer, which is commonly known as an ONO stack. In one embodiment, the dielectric material liner 56 can include a silicon oxide layer that is substantially free of carbon or a silicon oxynitride layer that is substantially free of carbon. The thickness of the dielectric material liner 56 can be in a range from 2 nm to 20 nm, although lesser and greater thicknesses can also be employed.

Referring to FIG. 5C, an optional sacrificial cover material layer 601 may be deposited over the dielectric material liner 56. The optional sacrificial cover material layer 601 includes a sacrificial material that can be subsequently removed selective to the material of the dielectric material liner 56. In one embodiment, the sacrificial cover material layer 601 can include a semiconductor material such as amorphous silicon, or may include a carbon-based material such as amorphous carbon or diamond-like carbon (DLC). The sacrificial cover material layer 601 can be formed by a conformal deposition method such as low pressure chemical vapor deposition (LPCVD). The thickness of the sacrificial cover material layer 601 can be in a range from 2 nm to 10 nm, although lesser and greater thicknesses can also be employed. A memory cavity 49′ is formed in the volume of each memory opening 49 that is not filled with the deposited material layers (501, 502, 54, 56, 601).

Referring to FIG. 5D, the optional sacrificial cover material layer 601, the dielectric material liner 56, the memory material layer 54, and the at least one blocking dielectric layer (501, 502) overlying the insulating cap layer 70 are sequentially anisotropically etched employing at least one anisotropic etch process. The portions of the sacrificial cover material layer 601, the dielectric material liner 56, the memory material layer 54, and the at least one blocking dielectric layer (501, 502) located above the top surface of the insulating cap layer 70 can be removed by the at least one anisotropic etch process. Further, the horizontal portions of the sacrificial cover material layer 601, the dielectric material liner 56, the memory material layer 54, and the at least one blocking dielectric layer (501, 502) at a bottom of each memory cavity 49′ can be removed to form openings in remaining portions thereof. Each of the sacrificial cover material layer 601, the dielectric material liner 56, the memory material layer 54, and the at least one blocking dielectric layer (501, 502) can be etched by a respective anisotropic etch process employing a respective etch chemistry, which may, or may not, be the same for the various material layers.

Each remaining portion of the sacrificial cover material layer 601 can have a tubular configuration. The memory material layer 54 can comprise a charge trapping material, a floating gate material, a ferroelectric material, or a resistive memory material that can provide at least two different levels of resistivity (such as a phase change material), or any other memory material that can store information by a change in state. In one embodiment, each memory material layer 54 can include a vertical stack of charge storage regions that store electrical charges upon programming. In one embodiment, the memory material layer 54 can be a memory material layer in which each portion adjacent to the metal layers 46 constitutes a charge storage region.

A surface of the semiconductor material layer 10 can be physically exposed underneath the opening through the sacrificial cover material layer 601, the dielectric material liner 56, the memory material layer 54, and the at least one blocking dielectric layer (501, 502). Optionally, the physically exposed semiconductor surface at the bottom of each memory cavity 49′ can be vertically recessed so that the recessed semiconductor surface underneath the memory cavity 49′ is vertically offset from the topmost surface of the semiconductor material layer 10 by a recess distance. A dielectric material liner 56 is located over the memory material layer 54. A set of at least one blocking dielectric layer (501, 502), a memory material layer 54, and a dielectric material liner 56 in a memory opening 49 constitutes a memory film 50, which includes a plurality of charge storage regions (as embodied as the memory material layer 54) that are insulated from surrounding materials by the at least one blocking dielectric layer (501, 502) and the dielectric material liner 56. In one embodiment, the sacrificial cover material layer 601, the dielectric material liner 56, the memory material layer 54, and the at least one blocking dielectric layer (501, 502) can have vertically coincident sidewalls. The sacrificial cover material layer 601 can be subsequently removed selective to the material of the dielectric material liner 56. In case the sacrificial cover material layer 601 includes a semiconductor material, a wet etch process employing hot trimethyl-2 hydroxyethyl ammonium hydroxide (“hot TMY”) or tetramethyl ammonium hydroxide (TMAH) can be performed to remove the sacrificial cover material layer 601. Alternatively, the sacrificial cover material layer 601 may be retained in the final device if it comprises a semiconductor material.

Referring to FIG. 5E, a semiconductor channel layer 60L can be deposited directly on the semiconductor surface of the semiconductor material layer 10, and directly on the dielectric material liner 56. The semiconductor channel layer 60L includes a semiconductor material such as at least one elemental semiconductor material, at least one III-V compound semiconductor material, at least one II-VI compound semiconductor material, at least one organic semiconductor material, or other semiconductor materials known in the art. In one embodiment, the semiconductor channel layer 60L includes amorphous silicon or polysilicon. The semiconductor channel layer 60L can have a doping of a first conductivity type, which is the same as the conductivity type of the semiconductor material layer 10. The semiconductor channel layer 60L can be formed by a conformal deposition method such as low pressure chemical vapor deposition (LPCVD). The thickness of the semiconductor channel layer 60L can be in a range from 2 nm to 10 nm, although lesser and greater thicknesses can also be employed. The semiconductor channel layer 60L may partially fill the memory cavity 49′ in each memory opening, or may fully fill the cavity in each memory opening.

Referring to FIG. 5F, in case the memory cavity 49′ in each memory opening is not completely filled by the semiconductor channel layer 60L, a dielectric core layer 62L can be deposited in the memory cavity 49′ to fill any remaining portion of the memory cavity 49′ within each memory opening. The dielectric core layer 62L includes a dielectric material such as silicon oxide or organosilicate glass. The dielectric core layer 62L can be deposited by a conformal deposition method such as low pressure chemical vapor deposition (LPCVD), or by a self-planarizing deposition process such as spin coating.

Referring to FIG. 5G, the horizontal portion of the dielectric core layer 62L can be removed, for example, by a recess etch process such that each remaining portions of the dielectric core layer 62L is located within a respective memory opening 49 and has a respective top surface below the horizontal plane including the top surface of the insulating cap layer 70. Each remaining portion of the dielectric core layer 62L constitutes a dielectric core 62.

Referring to FIG. 5H, a doped semiconductor material having a doping of a second conductivity type can be deposited within each recessed region above the dielectric cores 62. The deposited semiconductor material can have a doping of a second conductivity type that is the opposite of the first conductivity type. For example, if the first conductivity type is p-type, the second conductivity type is n-type, and vice versa. The dopant concentration in the deposited semiconductor material can be in a range from 5.0×10¹⁸/cm³ to 2.0×10²¹/cm³, although lesser and greater dopant concentrations can also be employed. The doped semiconductor material can be, for example, doped polysilicon.

Excess portions of the deposited semiconductor material having a doping of the second conductivity type and a horizontal portion of the semiconductor channel layer 60L can be removed from above the horizontal plane including the top surface of the insulating cap layer 70, for example, by chemical mechanical planarization (CMP) or a recess etch process. Each remaining portion of the doped semiconductor material having a doping of the second conductivity type constitutes a drain region 63. Each remaining portion of the semiconductor channel layer 60L (which has a doping of the first conductivity type) constitutes a vertical semiconductor channel 60. The vertical semiconductor channel 60 is formed directly on the dielectric material liner 56.

A dielectric material liner 56 is surrounded by a memory material layer 54, and laterally surrounds a portion of the vertical semiconductor channel 60. Each adjoining set of at least one blocking dielectric layer (501, 502), a memory material layer 54, and a dielectric material liner 56 collectively constitute a memory film 50, which can store electrical charges or electrical polarization with a macroscopic retention time. In some embodiments, a at least one blocking dielectric layer (501, 502) may not be present in the memory film 50 at this step, and a backside blocking dielectric layer may be subsequently formed after formation of backside recesses. As used herein, a macroscopic retention time refers to a retention time suitable for operation of a memory device as a permanent memory device such as a retention time in excess of 24 hours.

Each combination of a memory film 50 and a vertical semiconductor channel 60 within a memory opening 49 constitutes a memory stack structure 55. The memory stack structure 55 is a combination of a semiconductor channel, a dielectric material liner, a plurality of memory elements as embodied as portions of the memory material layer 54, and an optional at least one blocking dielectric layer (501, 502). An entire set of material portions that fills a memory opening 49 is herein referred to as a memory opening fill structure 58. An entire set of material portions that fills a support opening 19 constitutes a support pillar structure.

Generally, a memory opening fill structure 58 can be formed in each memory opening 49. The memory opening fill structure 58 comprises an optional at least one blocking dielectric layer (501, 502), a memory material layer 54, an optional dielectric material liner 56, and a vertical semiconductor channel 60. A dielectric material liner 56 may laterally surround the vertical semiconductor channel 60. The memory material layer 54 can laterally surround the dielectric material liner 56.

In case a at least one blocking dielectric layer (501, 502) is present in each memory opening fill structure 58, the blocking dielectric layer 501 may be formed on a sidewall of a memory opening 49, and the vertical stack of memory elements (which may comprise portions of the memory material layer 54) may be formed on the at least one blocking dielectric layer (501, 502). In one embodiment, the vertical stack of memory elements comprises portions of a charge storage layer (e.g., the memory material layer 54) located at the levels of the metal layers 46. In case a dielectric material liner 56 is present in each memory opening fill structure 58, the dielectric material liner 56 may be formed on the vertical stack of memory elements. In one embodiment, the dielectric material liner 56 may comprise a tunneling dielectric layer. In this case, the vertical semiconductor channel 60 can be formed on the tunneling dielectric layer. The at least one blocking dielectric layer (501, 502) laterally surrounds the charge storage layer and the tunneling dielectric layer can be located between the charge storage layer and the vertical semiconductor channel 60. A vertical NAND string can be formed through each memory opening upon formation of the memory opening fill structures 58.

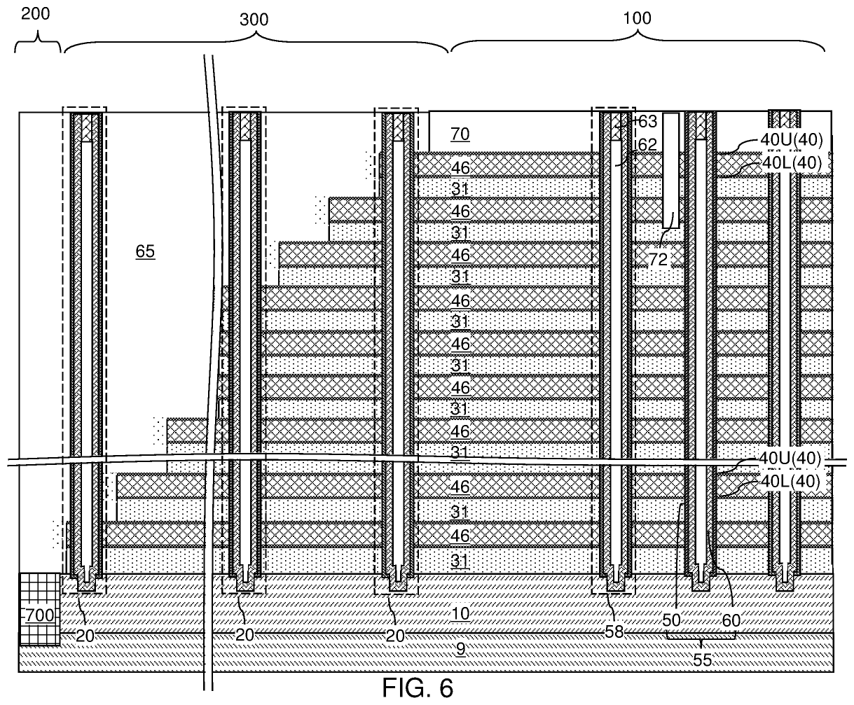

Referring to FIG. 6, the exemplary structure is illustrated after formation of memory opening fill structures 58 and support pillar structure 20 within the memory openings 49 and the support openings 19, respectively. An instance of a memory opening fill structure 58 can be formed within each memory opening 49 of the structure of FIGS. 4A and 4B. An instance of the support pillar structure 20 can be formed within each support opening 19 of the structure of FIGS. 4A and 4B.

Each memory stack structure 55 includes a vertical semiconductor channel 60 and a memory film 50. The memory film 50 may comprise a dielectric material liner 56 laterally surrounding the vertical semiconductor channel 60, a vertical stack of charge storage regions (comprising portions of the memory material layer 54 located at the levels of the metal layers 46) laterally surrounding the dielectric material liner 56, and an optional at least one blocking dielectric layer (501, 502). While the present disclosure is described employing the illustrated configuration for the memory stack structure, the methods of the present disclosure can be applied to alternative memory stack structures including different layer stacks or structures for the memory film 50 and/or for the vertical semiconductor channel 60.

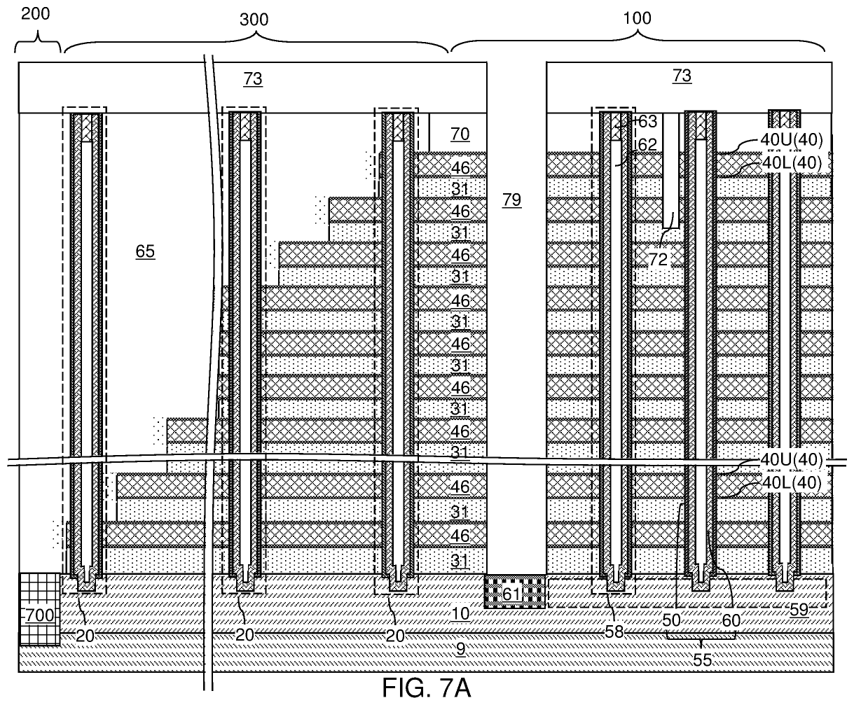

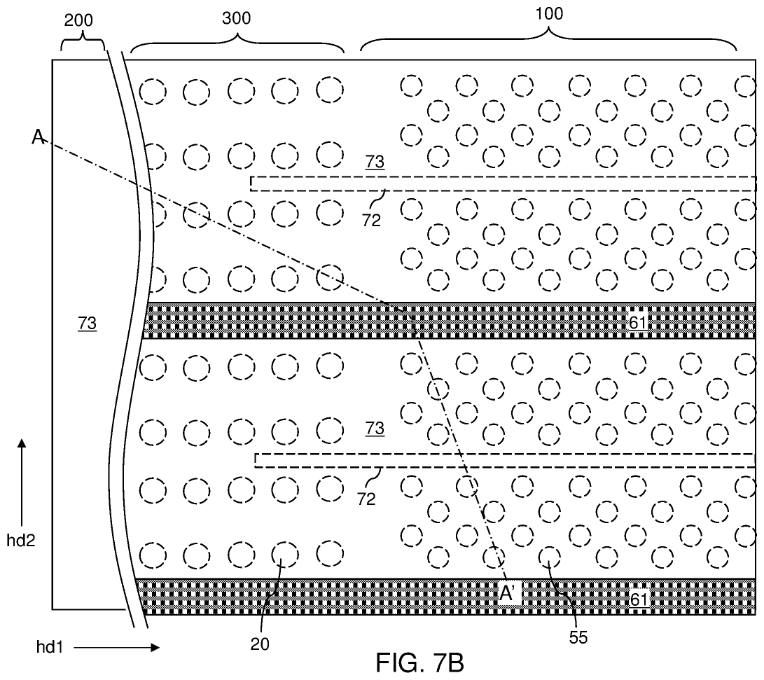

Referring to FIGS. 7A and 7B, a contact-level dielectric layer 73 can be formed over the vertical repetition of the unit layer stack (31, 40L, 46, 40U), and over the memory opening fill structures 58 and the support pillar structures 20. The contact-level dielectric layer 73 includes a dielectric material that is different from the dielectric material of the metal layers 46. For example, the contact-level dielectric layer 73 can include silicon oxide. The contact-level dielectric layer 73 can have a thickness in a range from 50 nm to 500 nm, although lesser and greater thicknesses can also be employed.

A photoresist layer (not shown) can be applied over the contact-level dielectric layer 73, and is lithographically patterned to form openings in areas between clusters of memory stack structures 55. The pattern in the photoresist layer can be transferred through the contact-level dielectric layer 73, the vertical repetition of the unit layer stack (31, 40L, 46, 40U) and/or the retro-stepped dielectric material portion 65 employing an anisotropic etch to form backside trenches 79, which vertically extend from the top surface of the contact-level dielectric layer 73 at least to the top surface of the substrate (9, 10), and laterally extend through the memory array region 100 and the contact region 300.

In one embodiment, the backside trenches 79 can laterally extend along a first horizontal direction (e.g., word line direction) hd1 and can be laterally spaced apart among one another along a second horizontal direction (e.g., bit line direction) hd2 that is perpendicular to the first horizontal direction hd1. The memory stack structures 55 can be arranged in rows that extend along the first horizontal direction hd1. The drain-select-level isolation structures 72 can laterally extend along the first horizontal direction hd1. Each backside trench 79 can have a uniform width that is invariant along the lengthwise direction (i.e., along the first horizontal direction hd1). Each drain-select-level isolation structure 72 can have a uniform vertical cross-sectional profile along vertical planes that are perpendicular to the first horizontal direction hd1 that is invariant with translation along the first horizontal direction hd1. Multiple rows of memory stack structures 55 can be located between a neighboring pair of a backside trench 79 and a drain-select-level isolation structure 72, or between a neighboring pair of drain-select-level isolation structures 72. In one embodiment, the backside trenches 79 can include a source contact opening in which a source contact via structure can be subsequently formed. The photoresist layer can be removed, for example, by ashing.

A source region 61 can be formed at a surface portion of the semiconductor material layer 10 under each backside trench 79 by implantation of electrical dopants into physically exposed surface portions of the semiconductor material layer 10. An upper portion of the semiconductor material layer 10 that extends between the source region 61 and the bottom portions of the vertical semiconductor channels 60 constitutes a horizontal semiconductor channel 59 for a plurality of field effect transistors. The horizontal semiconductor channel 59 is connected to multiple vertical semiconductor channels 60. The horizontal semiconductor channel 59 contacts the source region 61 and a plurality of vertical semiconductor channels 60.

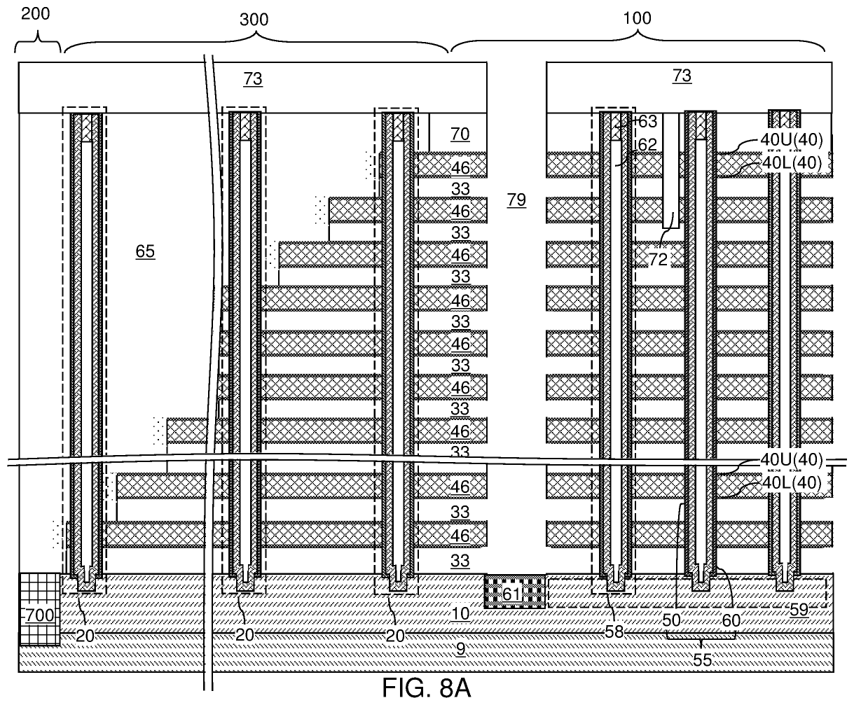

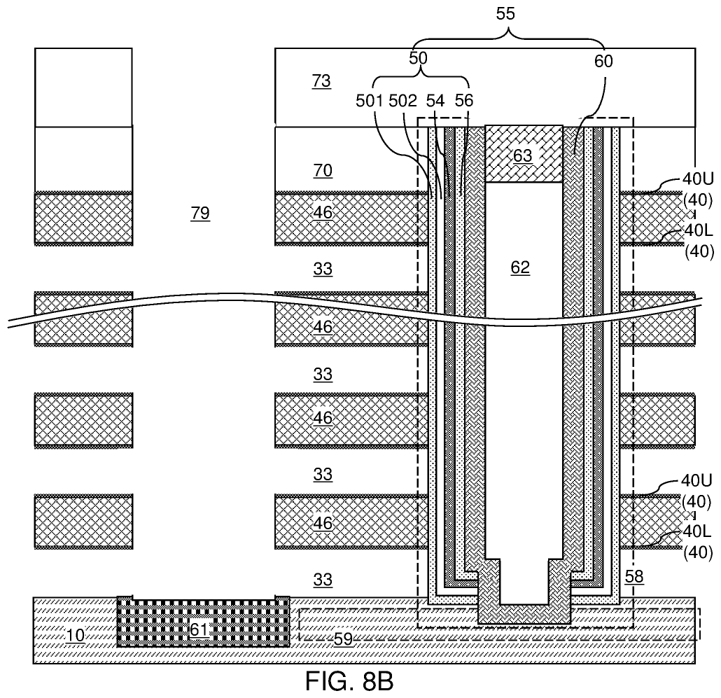

Referring to FIGS. 8A and 8B, an etchant that selectively etches the material of the sacrificial material layers 31 selective to the materials of the metal layers 46 and the interfacial dielectric capping layers 40 can be introduced into the backside trenches 79, for example, employing an etch process. Backside recesses 33 are formed in volumes from which the instances of the sacrificial material layer 31 are removed selective to the instances of the first interfacial dielectric capping layer 40L, the metal layer 46, and the second interfacial dielectric capping layer 40U. The removal of the material of the sacrificial material layers 31 can be selective to the material of the retro-stepped dielectric material portion 65, to the semiconductor material of the semiconductor material layer 10, and optionally to the material of the outermost layer of the memory films 50. In one embodiment, the removal of the material of the sacrificial material layers 31 can be selective to the material of the first blocking dielectric layer 501. In one embodiment, the sacrificial material layers 31 may include silicon nitride, organosilicate glass, or borosilicate glass, and the retro-stepped dielectric material portion 65 can include undoped silicate glass.

The etch process that removes the material of the sacrificial material layers 31 selective to the metal layers 46, the interfacial dielectric capping layers 40, and the outermost layers of the memory films 50 can be a wet etch process employing a wet etch solution, or can be a gas phase (dry) etch process in which the etchant is introduced in a vapor phase into the backside trenches 79. For example, if the sacrificial material layers 31 comprise silicon nitride, the etch process can be a wet etch process in which the exemplary structure is immersed within a wet etch tank including phosphoric acid, which etches silicon nitride selective to silicon oxide, silicon, and various other materials employed in the art. If the sacrificial material layers 31 comprise organosilicate glass or borosilicate glass, the etch process can be a wet etch process in which the exemplary structure is immersed within a wet etch tank including dilute hydrofluoric acid, which etches organosilicate glass or borosilicate glass at an etch rate that is at least 100 times higher than the etch rate of undoped silicate glass. The duration of the etch process and the dilution of the hydrofluoric acid can be controlled to minimize collateral etching of undoped silicate glass. The support pillar structure 20, the retro-stepped dielectric material portion 65, and the memory opening fill structures 58 provide structural support while the backside recesses 33 are present within volumes previously occupied by the metal layers 46.

Each backside recess 33 can be a laterally extending cavity having a lateral dimension that is greater than the vertical extent of the cavity. In other words, the lateral dimension of each backside recess 33 can be greater than the height of the backside recess 33. A plurality of backside recesses 33 can be formed in the volumes from which the sacrificial material layers 31 are removed. The memory openings in which the memory opening fill structures 58 are formed are herein referred to as front side openings or front side cavities in contrast with the backside recesses 33. In one embodiment, the memory array region 100 comprises an array of monolithic three-dimensional NAND strings having a plurality of device levels disposed above the substrate (9, 10). In this case, each backside recess 33 provides vertical spacing between neighboring pairs of word lines 46 of the array of three-dimensional NAND strings.

Each of the plurality of backside recesses 33 can extend substantially parallel to the top surface of the substrate (9, 10). A backside recess 33 can be vertically bounded by a top surface of an underlying second interfacial dielectric capping layer 40U and a bottom surface of an overlying first interfacial dielectric capping layer 40L. In one embodiment, each backside recess 33 can have a uniform height throughout.

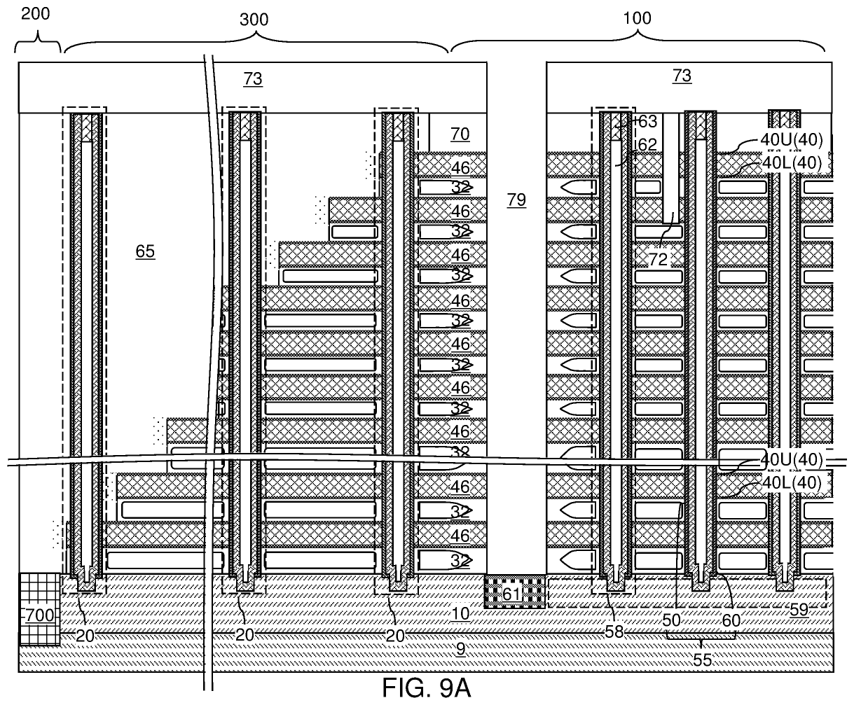

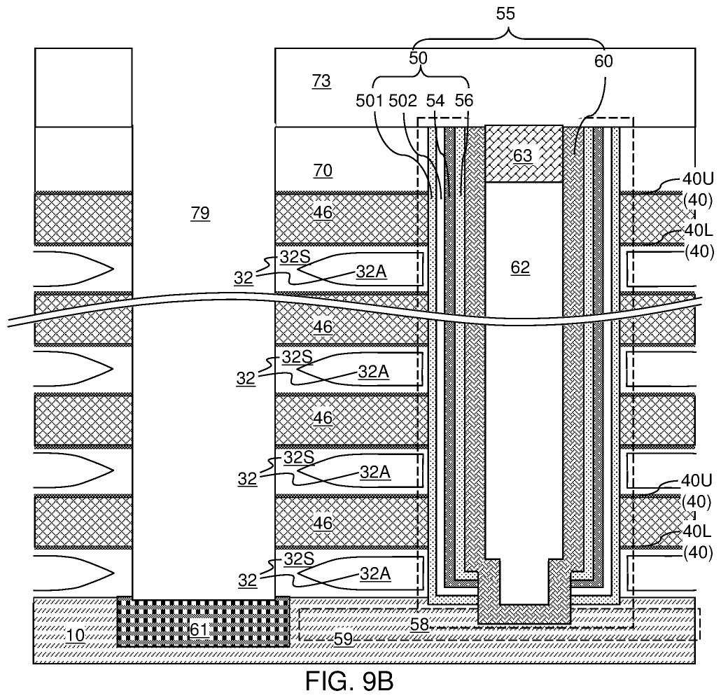

Referring to FIGS. 9A and 9B, an airgap-containing insulating layer 32 can be in each of the backside recesses 33 by anisotropically depositing a dielectric material and anisotropically etching portions of the deposited dielectric material from inside the backside trenches 79 and from above the contact-level dielectric layer 73. In one embodiment, the dielectric material may comprise silicon oxide.

According to an aspect of the present disclosure, the anisotropic nature of the deposition process that deposits the silicon oxide dielectric material result formation of encapsulated airgaps 32A that are enclosed by a respective solid-phase dielectric material portion 32S, such as a silicon oxide portion. The combination of an encapsulated airgap 32A and a solid-phase dielectric material portion 32S that is formed within each backside recess 33 constitutes an insulating layer 32, which has an effective dielectric constant that is less than the dielectric constant of the solid-phase dielectric material portions 32S. In one embodiment, the anisotropic etch process can be performed such that sidewalls of the airgap-containing insulating layers 32 (i.e., sidewalls of the solid-phase dielectric material portion 32S) that are physically exposed to the backside trenches 79 are vertically coincident with overlying or underlying sidewalls of the metal layers 46 that are physically exposed to the same backside trench 79.

Generally, instances of the sacrificial material layer 31 within the vertical repetition of instances of the unit layer stack (31, 40L, 46, 40U) as formed at the processing steps of FIG. 2 are replaced with instances of an insulating layer, which may be instances of an airgap-containing insulating layer 32. In this case, each instance of the insulating layer comprises an instance of an airgap-containing insulating layer 32, which comprises a dielectric material portion (such as a solid-phase dielectric material portion 32S) encapsulating an encapsulated airgap 32A therein. In one embodiment, the instances of the insulating layer (such as the airgap-containing insulating layer 32) are formed on outer sidewalls of the at least one blocking dielectric layer (501, 502) of each of the memory films 50.

A vertical repetition of instances of a modified unit layer stack is provided. The modified unit layer stack includes, in order from bottom to top or from top to bottom, an insulating layer (such as an airgap-containing insulating layer 32), a first interfacial dielectric capping layer 40L, a metal layer 46, and a second interfacial dielectric capping layer 40U. In one embodiment, memory openings 49 vertically extend through the vertical repetition, and memory opening fill structures 58 are located within the respective memory openings 49. Each of the memory opening fill structures 58 comprises a respective set of at least one blocking dielectric layer (501, 502) vertically extending through the vertical repetition (32, 40L, 46, 40U). In one embodiment, each of the airgap-containing insulating layers 32 contacts a respective segment of an outer sidewall of each set of at least one blocking dielectric layer (501, 502).

In one embodiment, each vertical repetition of the unit layer stack (32, 40L, 46, 40U) can be located between a respective neighboring pair of backside trenches 79 that laterally extend along a first horizontal direction hd1. A plurality of memory opening fill structures 58 can vertically extend through a vertical repetition of the unit layer stack (32, 40L, 46, 40U) located between a respective neighboring pair of backside trenches 79. Each of the encapsulated airgaps 32A within the airgap-containing insulating layers 32 in the vertical repetition of the unit layer stack (32, 40L, 46, 40U) laterally surrounds each of the memory opening fill structures 58 vertically extending through the vertical repetition of the unit layer stack (32, 40L, 46, 40U). In other words, each encapsulated airgaps 32A may continuously extend laterally such that each encapsulated airgap 32A laterally surrounds each memory opening fill structure 58 that extends through a same vertical repetition of the unit layer stack (32, 40L, 46, 40U) that is located between a pair of backside trenches 79.

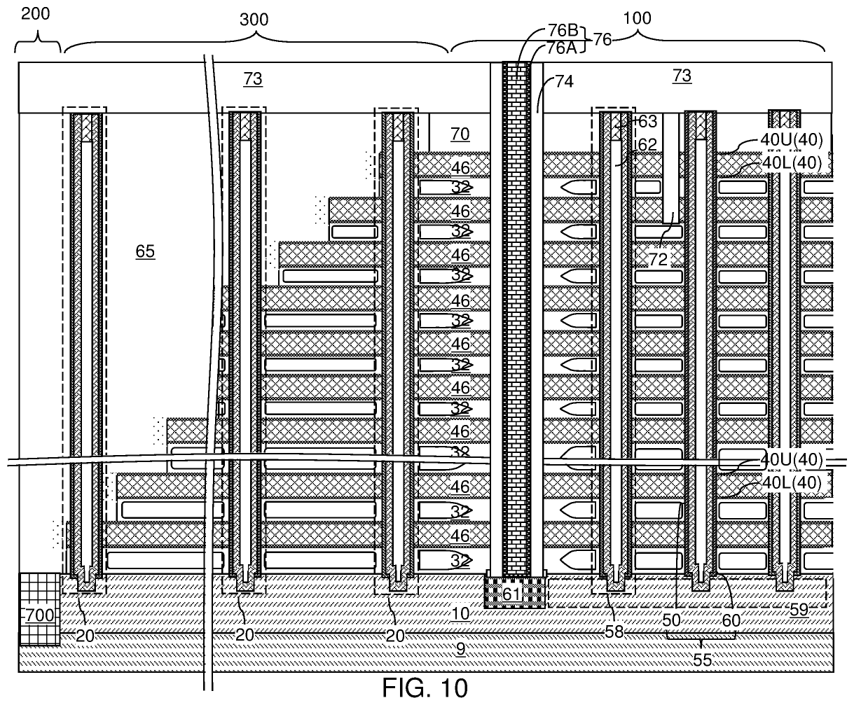

Referring to FIG. 10, an insulating material layer can be formed in the backside trenches 79 and over the contact-level dielectric layer 73 by a conformal deposition process. Exemplary conformal deposition processes include, but are not limited to, chemical vapor deposition and atomic layer deposition. The insulating material layer includes an insulating material such as silicon oxide, silicon nitride, a dielectric metal oxide, an organosilicate glass, or a combination thereof. In one embodiment, the insulating material layer can include silicon oxide. The insulating material layer can be formed, for example, by low pressure chemical vapor deposition (LPCVD) or atomic layer deposition (ALD). The thickness of the insulating material layer can be in a range from 1.5 nm to 60 nm, although lesser and greater thicknesses can also be employed.

An anisotropic etch is performed to remove horizontal portions of the insulating material layer from above the contact-level dielectric layer 73 and at the bottom of each backside trench 79. Each remaining portion of the insulating material layer constitutes an insulating spacer 74. A backside cavity is present within a volume surrounded by each insulating spacer 74. A top surface of the semiconductor material layer 10 can be physically exposed at the bottom of each backside trench 79.

A backside contact via structure 76 can be formed within each backside cavity. Each contact via structure 76 can fill a respective cavity. The contact via structures 76 can be formed by depositing at least one conductive material in the remaining unfilled volume (i.e., the backside cavity) of the backside trench 79. For example, the at least one conductive material can include a conductive liner 76A and a conductive fill material portion 76B. The conductive liner 76A can include a conductive metallic liner such as TiN, TaN, WN, TiC, TaC, WC, an alloy thereof, or a stack thereof. The thickness of the conductive liner 76A can be in a range from 3 nm to 30 nm, although lesser and greater thicknesses can also be employed. The conductive fill material portion 76B can include a metal or a metallic alloy. For example, the conductive fill material portion 76B can include W, Cu, Al, Co, Ru, Ni, an alloy thereof, or a stack thereof.

The at least one conductive material can be planarized employing the contact-level dielectric layer 73 overlying the vertical repetition of instances of the unit layer stack (32, 40L, 46, 40U) as a stopping layer. If chemical mechanical planarization (CMP) process is employed, the contact-level dielectric layer 73 can be employed as a CMP stopping layer. Each remaining continuous portion of the at least one conductive material in the backside trenches 79 constitutes a backside contact via structure 76.

The backside contact via structure 76 extends through the vertical repetition of instances of the unit layer stack (32, 40L, 46, 40U), and contacts a top surface of the source region 61. If an airgap-containing insulating layer 32 is employed, the backside contact via structure 76 can contact a sidewall of the airgap-containing insulating layer 32.

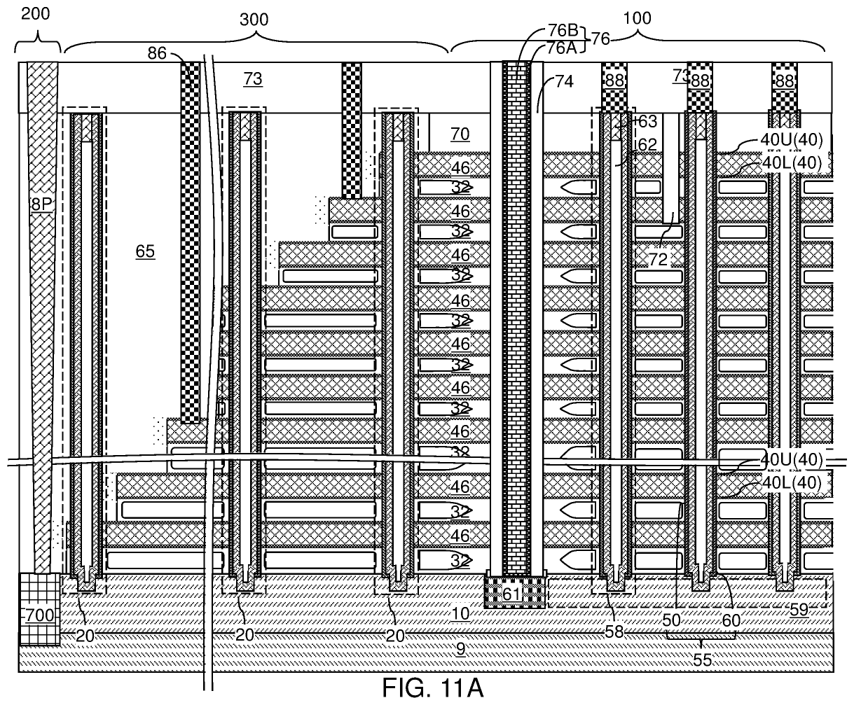

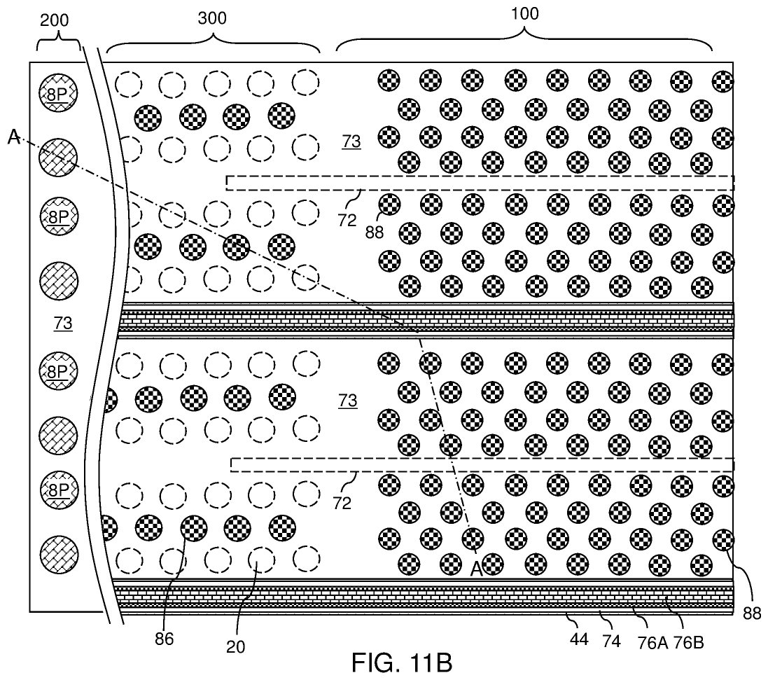

Referring to FIGS. 11A and 11B, additional contact via structures (88, 86, 8P) can be formed through the contact-level dielectric layer 73, and optionally through the retro-stepped dielectric material portion 65. For example, drain contact via structures 88 can be formed through the contact-level dielectric layer 73 on each drain region 63. Word line contact via structures 86 can be formed on the metal layers 46 through the contact-level dielectric layer 73, and through the retro-stepped dielectric material portion 65. Peripheral device contact via structures 8P can be formed through the retro-stepped dielectric material portion 65 directly on respective nodes of the peripheral devices.

Alternatively, the above described insulating material layer can be formed in the backside trenches 79 to completely fill the entire volume of a backside trench 79 and may consist essentially of at least one dielectric material. In this alternative embodiment, the source region 61 and the backside trench via structure 76 may be omitted, and a horizontal source line (e.g., direct strap contact) may contact an side of the lower portion of the semiconductor channel 60.

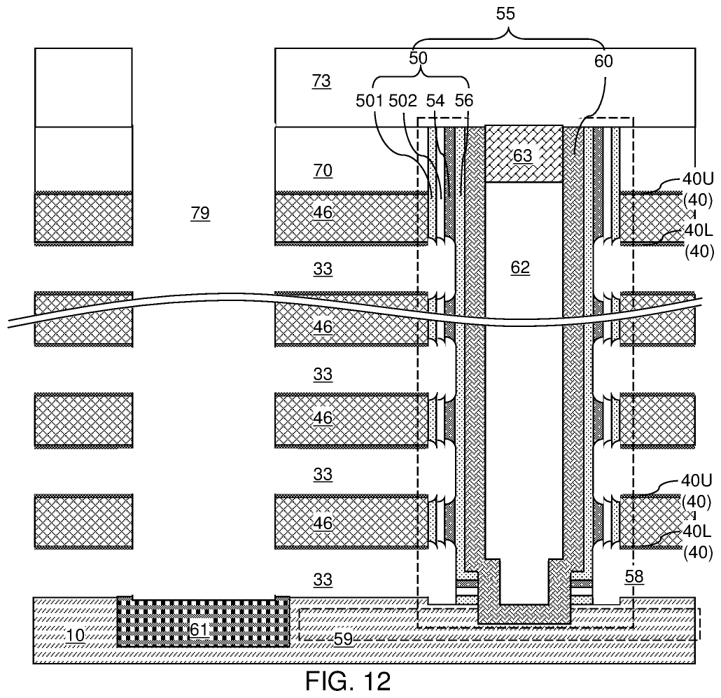

Referring to FIG. 12, an alternative configuration of the exemplary structure according to an embodiment of the present disclosure is illustrated, which can be derived from the exemplary structure illustrated in FIGS. 8A and 8B by sequentially etching physically exposed portions of at least one blocking dielectric layer (501, 502) and a memory material layer 54 within each memory film 50. For example, a first isotropic etch process that etches the material of the first blocking dielectric layers 501 can be performed to isotropically etch physically exposed portions of the first blocking dielectric layers 501, a second isotropic etch process that etches the material of the second blocking dielectric layers 502 can be performed to isotropically etch physically exposed portions of the second blocking dielectric layers 502, and a third isotropic etch process that etches the material of the memory material layers 54 can be performed to isotropically etch physically exposed portions of the memory material layers 54. In one embodiment, if the first blocking dielectric layers 501 comprise aluminum oxide, the first isotropic etch process may comprise a wet etch process employing a mixture of phosphoric acid, nitric acid, and acetic acid. If the second blocking dielectric layers 502 comprise silicon oxide, the second isotropic etch process may comprise a wet etch process employing dilute hydrofluoric acid. If the memory material layers 54 comprise silicon nitride, the third isotropic etch process may comprise a wet etch process employing hot phosphoric acid.

In the alternative configuration of the exemplary structure, physically exposed portions of the at least one blocking dielectric layer (501, 502) within each of the memory films 50 can be removed around the backside recesses 33. Subsequently, physically exposed portions of the memory material layer 54 within each of the memory films 50 can be removed around the backside recesses 33. Remaining portions of the at least one blocking dielectric layer (501, 502) and a memory material layer 54 comprise a vertical stack of first discrete blocking dielectric material portions that are remaining portions of the first blocking dielectric layer 501, a vertical stack of second discrete blocking dielectric material portions that are remaining portions of the second blocking dielectric layer 502, and a vertical stack of discrete memory material portions that are remaining portions of the memory material layer 54. In one embodiment, each discrete element within the vertical stack of first discrete blocking dielectric material portions, the vertical stack of second discrete blocking dielectric material portions, and the vertical stack of discrete memory material portions may have a tubular configuration, and may comprise at least one concave annular surface, such as a pair of concave annular surfaces, that is physically exposed to a respective one of the backside recesses 33. Each vertical stack of discrete memory material portions comprises a vertical stack of vertically separated memory elements within a respective one of the memory films 50.

In one embodiment, the discrete memory material portions comprise a charge storage material that can store electrical charge therein. The charge storage material may comprise a dielectric material (e.g., silicon nitride regions) or a conductive material (e.g., metal, metal alloy or heavily doped polysilicon floating gates).

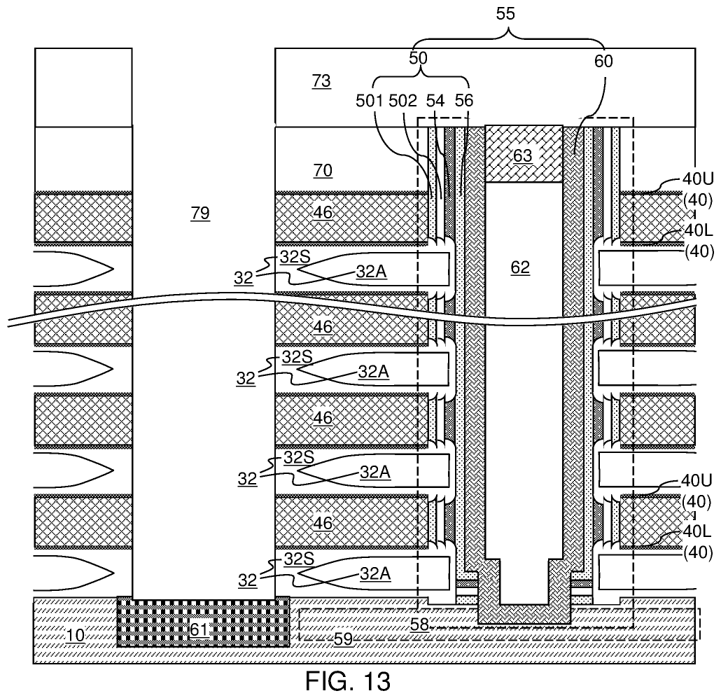

Referring to FIG. 13, the processing steps of FIGS. 9A and 9B can be performed to form the airgap-containing insulating layer 32 within each of the backside recesses 33. Instances of the airgap-containing insulating layer 32 can be formed directly on horizontal surfaces of the discrete memory elements to vertically separate and electrically isolate the memory elements from each other. In one embodiment, each vertical stack of memory elements comprises a vertical stack of discrete charge storage material portions that can store electrical charge therein. In one embodiment, at least one discrete charge storage material portion within the vertical stack of discrete charge storage material portions comprises: an upper concave surface segment contacting a convex surface segment of a first instance of the airgap-containing insulating layer 32; and a lower concave surface segment contacting a convex surface segment of a second instance of the airgap-containing insulating layer 32.

In one embodiment, at least one discrete charge storage material portion within the vertical stack of discrete charge storage material portions contacts an inner sidewall of a respective blocking dielectric material portion (which may be a patterned portion of the second blocking dielectric layer 502); and the blocking dielectric material portion contacts a surface segment of a first instance of the airgap-containing insulating layer 32 and a surface segment of a second instance of the airgap-containing insulating layer 32. The airgap-containing insulating layers 32 may contact a vertical sidewall of the liner (e.g., tunneling dielectric) 56.

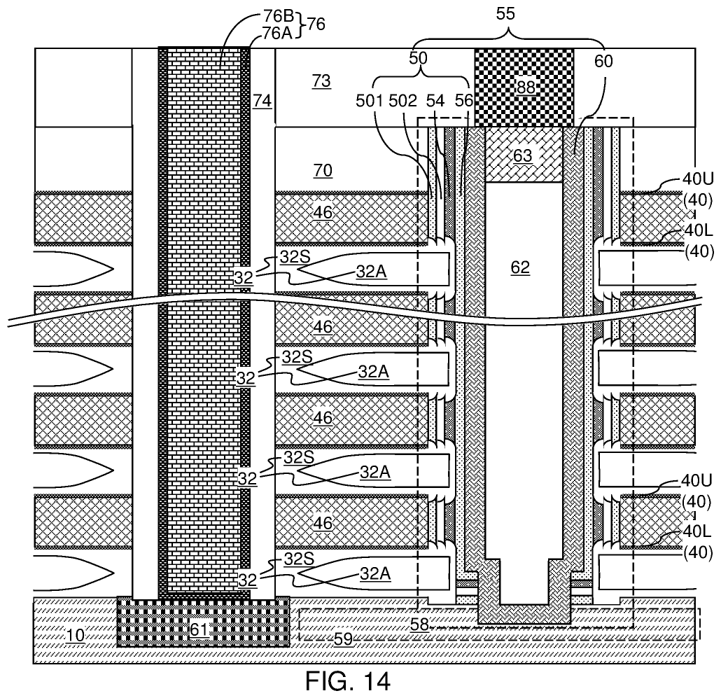

Referring to FIG. 14, the processing steps of FIGS. 10 and 11 can be performed to form various contact via structures (76, 88, 86, 8P).

Referring to all drawings and according to various embodiments of the present disclosure, a three-dimensional memory device is provided, which comprises: a vertical repetition of multiple instances of a unit layer stack comprising, in order, an airgap-containing insulating layer 32, a first interfacial dielectric capping layer 40L, a metal layer 46, and a second interfacial dielectric capping layer 40U; and memory stack structures 55 extending through the vertical repetition (32, 40L, 46, 40U), wherein each of the memory stack structures 55 comprises a vertical semiconductor channel 60 and a vertical stack of memory elements located at levels of the metal layers 46.

In one embodiment, each of the airgap-containing insulating layers 32 comprises a dielectric material portion (such as a solid-phase dielectric material portion 32S) encapsulating a respective encapsulated airgap 32A.

In one embodiment the three-dimensional memory device comprises a pair of backside trench fill structures (74, 76) laterally extending along a first horizontal direction hd1 and contacting sidewalls of the vertical repetition (32, 40L, 46, 40U), wherein each of the memory opening fill structures 58 is located between the pair of backside trench fill structures (74, 76).

In one embodiment, each of the encapsulated airgaps 32A laterally surrounds each of the memory opening fill structures 58 and is located between the pair of backside trench fill structures (74, 76).

In one embodiment, the first interfacial dielectric capping layer 40L comprises a first oxygen-free dielectric material; and the second interfacial dielectric capping layer 40U comprises a second oxygen-free dielectric material.

In one embodiment, the first oxygen-free dielectric material is selected from silicon carbide, silicon nitride, or silicon carbide nitride; and the second oxygen-free dielectric material is selected from silicon carbide, silicon nitride, or silicon carbide nitride.

In one embodiment, an average thickness of the first interfacial dielectric capping layers 40L is less than 20% of an average thickness of the metal layers 46; and an average thickness of the second interfacial dielectric capping layers 40U is less than 20% of the average thickness of the metal layers 46.

In one embodiment, each of the metal layers 46 comprises molybdenum at an atomic percentage that is greater than 90%. In one embodiment, each of the metal layers 46 consists essentially of molybdenum.

In one embodiment, the vertical stack of memory elements comprises a vertical stack of discrete charge storage material portions located at levels of the metal layers 46. In one embodiment, a discrete charge storage material portion within the vertical stack of discrete charge storage material portions comprises: an upper concave surface segment contacting a convex surface segment of a first instance of the airgap-containing insulating layer 32; and a lower concave surface segment contacting a convex surface segment of a second instance of the airgap-containing insulating layer 32. In one embodiment, a discrete charge storage material portion within the vertical stack of discrete charge storage material portions contacts an inner sidewall of a blocking dielectric material portion (such as a patterned portion of the second blocking dielectric layer 502); and the blocking dielectric material portion contacts a surface segment of a first instance of the airgap-containing insulating layer 32 and a surface segment of a second instance of the airgap-containing insulating layer 32.

In another embodiment, the vertical stack of memory elements comprises portions of a continuous memory material layer 54 that continuously vertically extends through the vertical repetition (32, 40L, 46, 40U). In one embodiment, each of the memory stack structures 55 comprises at least one blocking dielectric layer (501, 502) vertically extending through the vertical repetition and contacting an outer sidewall of a respective memory material layer 54. In one embodiment, the at least one blocking dielectric layer (501, 502) comprises an outer aluminum oxide blocking dielectric layer 501 and an inner silicon oxide blocking dielectric layer 502 located between the outer aluminum oxide blocking dielectric layer 501 and the respective continuous memory material layer 54.

The various embodiments of the present disclosure can be employed to provide a three-dimensional memory array in which metal gates (e.g., select gate electrodes and control gate electrodes/word lines) may be formed by deposition and etching instead of by replacing sacrificial material layers with the metal gates. The memory opening fill structures may be formed after the metal gates are already deposited. This simplifies the process and allows the scaling of memory opening fill structures. Furthermore, it may avoid fluorine outgassing damage to the memory opening fill structures that may result from forming the metal gates using a fluorine containing precursor gas (e.g., tungsten hexafluoride) after forming the memory opening fill structures. Furthermore, metal oxide blocking dielectric layers may be formed in the memory openings rather than in backside recesses, which permits thicker, lower resistivity metal gates to be formed.

If airgaps are formed between the metal gates, then the space between neighboring pairs of metal gates has a lower dielectric constant than the dielectric constant of the material of the solid-phase dielectric material portions. The interfacial dielectric capping layers block or reduce diffusion of oxygen atoms into the metal gates, and thus, prevent or reduce oxidation of the metal gates, which decreases the roughness of the metal gates.

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Where an embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. All of the publications, patent applications and patents cited herein are incorporated herein by reference in their entirety.

What is claimed is:

1. A three-dimensional memory device, comprising:
a vertical repetition of multiple instances of a unit layer stack comprising, in order, an airgap-containing insulating layer, a first interfacial dielectric capping layer, a metal layer, and a second interfacial dielectric capping layer; and
memory stack structures extending through the vertical repetition, wherein each of the memory stack structures comprises a vertical semiconductor channel and a vertical stack of memory elements located at levels of the metal layers.

2. The three-dimensional memory device of claim 1, wherein each of the airgap-containing insulating layers comprises a dielectric material portion encapsulating a respective encapsulated airgap.

3. The three-dimensional memory device of claim 2, further comprising a pair of backside trench fill structures laterally extending along a first horizontal direction and contacting sidewalls of the vertical repetition, wherein each of the memory opening fill structures is located between the pair of backside trench fill structures.

4. The three-dimensional memory device of claim 3, wherein each of the encapsulated airgaps laterally surrounds each of the memory opening fill structures and is located between the pair of backside trench fill structures.

5. The three-dimensional memory device of claim 1, wherein:
the first interfacial dielectric capping layer comprises a first oxygen-free dielectric material; and
the second interfacial dielectric capping layer comprises a second oxygen-free dielectric material.

6. The three-dimensional memory device of claim 5, wherein:
the first oxygen-free dielectric material is selected from silicon carbide, silicon nitride, or silicon carbide nitride; and
the second oxygen-free dielectric material is selected from silicon carbide, silicon nitride, or silicon carbide nitride.

7. The three-dimensional memory device of claim 1, wherein:
an average thickness of the first interfacial dielectric capping layers is less than 20% of an average thickness of the metal layers; and
an average thickness of the second interfacial dielectric capping layers is less than 20% of the average thickness of the metal layers.

8. The three-dimensional memory device of claim 1, wherein the metal layers comprise molybdenum at an atomic percentage that is greater than 90%.

9. The three-dimensional memory device of claim 1, wherein the vertical stack of memory elements comprises a vertical stack of discrete charge storage material portions located at levels of the metal layers.

10. The three-dimensional memory device of claim 9, wherein a discrete charge storage material portion within the vertical stack of discrete charge storage material portions comprises:
an upper concave surface segment contacting a convex surface segment of a first instance of the airgap-containing insulating layer; and
a lower concave surface segment contacting a convex surface segment of a second instance of the airgap-containing insulating layer.

11. The three-dimensional memory device of claim 9, wherein:
a discrete charge storage material portion within the vertical stack of discrete charge storage material portions contacts an inner sidewall of a blocking dielectric material portion; and
the blocking dielectric material portion contacts a surface segment of a first instance of the airgap-containing insulating layer and a surface segment of a second instance of the airgap-containing insulating layer.

12. The three-dimensional memory device of claim 1, wherein the vertical stack of memory elements comprises portions of a continuous memory material layer that continuously vertically extends through the vertical repetition.

13. The three-dimensional memory device of claim 12, wherein each of the memory stack structures comprises at least one blocking dielectric layer vertically extending through the vertical repetition and contacting an outer sidewall of a respective continuous memory material layer.

14. The three-dimensional memory device of claim 13, wherein the at least one blocking dielectric layer comprises an outer aluminum oxide blocking dielectric layer and an inner silicon oxide blocking dielectric layer located between the outer aluminum oxide blocking dielectric layer and the respective continuous memory material layer.

15. A method of forming a three-dimensional memory device, comprising:
forming a vertical repetition of multiple instances of a unit layer stack over a substrate, wherein the unit layer stack comprises, in order, a sacrificial material layer, a first interfacial dielectric capping layer, a metal layer, and a second interfacial dielectric capping layer;
forming memory openings through the vertical repetition;
forming memory opening fill structures in the memory openings, wherein each of the memory opening fill structures comprises a vertical semiconductor channel and a vertical stack of memory elements located at levels of the metal layers; and
replacing the sacrificial material layers within the vertical repetition with insulating layers.

16. The method of claim 15, wherein the insulating layers comprise airgap-containing insulating layers.

17. The method of claim 15, further comprising:
forming backside trenches through the vertical repetition;
forming backside recesses by removing the sacrificial material layer selective to the first interfacial dielectric capping layer, the metal layer, and the second interfacial dielectric capping layer; and
forming the insulating layers within the backside recesses.

18. The method of claim 15, wherein:
the metal layers are formed by ion beam deposition;
forming memory opening fill structures comprises forming a memory film including at least one blocking dielectric layer, a memory material layer, and a dielectric material liner in each of the memory openings;
portions of the memory material layer located at levels of the metal layers comprise the vertical stack of memory elements within each of the memory opening fill structures; and
the vertical semiconductor channel is formed on the dielectric material liner within each of the memory opening fill structures.

19. The method of claim 18, further comprising forming backside recesses by removing the sacrificial material layers selective to the memory films and selective to the first interfacial dielectric capping layer, the metal layer, and the second interfacial dielectric capping layer, wherein the insulating layers are formed on outer sidewalls of the at least one blocking dielectric layer of each of the memory films.

20. The method of claim 18, further comprising:
forming backside recesses by removing the sacrificial material layers selective to the first interfacial dielectric capping layer, the metal layer, and the second interfacial dielectric capping layer;
removing physically exposed portions of the at least one blocking dielectric layer within each of the memory films around the backside recesses; and
removing physically exposed portions of the memory material layer within each of the memory films around the backside recesses,
wherein:
remaining portions of the memory material layer comprise the vertical stack of memory elements within each of the memory films; and
the insulating layers are formed directly on horizontal surfaces of the vertical stacks of memory elements.
